(19) United States
(12) Patent Application Publication
(10) Pub. No.: US 2024/0244876 A1
(43) Pub. Date: Jul. 18, 2024

(54) DISPLAY DEVICE

(71) Applicant: LG Display Co., Ltd., Seoul (KR)

(72) Inventors: KwangJong KIM, Seoul (KR); Jisu MOON, Seoul (KR)

(73) Assignee: LG Display Co., Ltd., Seoul (KR)

(21) Appl. No.: 18/396,447

(22) Filed: Dec. 26, 2023

(30) Foreign Application Priority Data
Jan. 13, 2023 (KR) 10-2023-0005393

(51) Int. Cl. H10K 50/828; H10K 50/818; H10K 59/122; H10K 59/80

(52) U.S. Cl. CPC H10K 50/828; H10K 50/818; H10K 59/122; H10K 59/878

(57) ABSTRACT

A display device includes a transistor above a substrate, a planarization layer above the transistor and having a first open area, an anode electrode in the first open area as well as a side portion and a part of a top surface of the planarization layer opposite to the first open area, a bank covering a part of the anode electrode and having a second open area corresponding to the first open area, an organic layer on the anode electrode exposed by the second open area, a cathode electrode on the organic layer, and a capping layer above the cathode electrode and including a first capping layer having a first refractive index, a second capping layer having a second refractive index, and a third capping layer having a third refractive index. The first refractive index and the third refractive index are relatively lower than the second refractive index.

### CROSS-REFERENCE TO RELATED APPLICATIONS

This application claims the priority of Korean Patent Application No. 10-2023-0005393 filed on Jan. 13, 2023, in the Korean Intellectual Property Office, the disclosure of which is incorporated herein by reference.

### BACKGROUND

### Technical Field

The present disclosure relates to a display device.

### Discussion of the Related Art

As it enters the information era, a field of a display device which visually expresses electrical information signals has been rapidly developed and studies are continued to improve performances of various display devices, such as a thin-thickness, a light weight, and low power consumption.

A representative display device may include a liquid crystal display (LCD) device, a field emission display (FED) device, an electro-wetting display (EWD) device, and an organic light emitting display (OLED) device.

An electroluminescent display device which is represented by an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, and a contrast ratio (CR), it is expected to be utilized in various fields.

The electroluminescent display device configures a light emitting diode by disposing a plurality of organic layers each including an emission layer between two electrodes of an anode electrode and a cathode electrode. For example, when holes are injected from the anode electrode into the emission layer and electrons are injected from the cathode electrode into the emission layer, the injected holes and electrons are recombined in the emission layer to form excitons and emit light.

However, the electroluminescent display device has a problem in that there is light which does not go out from a display panel and is trapped in the display panel, among light emitted from the emission layer so that a light extraction efficiency is degraded and a luminous efficiency is degraded.

### SUMMARY

Accordingly, embodiments of the present disclosure are directed to a display device that substantially obviates one or more of the problems due to limitations and disadvantages of the related art.

An aspect of the present disclosure is to provide a display device with an improved light extraction efficiency.

Another aspect of the present disclosure is to provide a display device which improves a front efficiency and a viewing angle.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including a plurality of sub pixels, a transistor disposed above the substrate, a planarization layer which is disposed above the transistor and has a first open area, an anode electrode which is disposed in the first open area and a side portion and a part of a top surface of the planarization layer opposite to the first open area, a bank which covers a part of the anode electrode and has a second open area corresponding to the first open area, an organic layer which is disposed on the anode electrode exposed by the second open area, a cathode electrode disposed on the organic layer and a capping layer which is disposed above the cathode electrode and includes a first capping layer having a first refractive index, a second capping layer having a second refractive index, and a third capping layer having a third refractive index, the first refractive index and the third refractive index may be relatively lower than the second refractive index.

Other detailed matters of the exemplary embodiments are included in the detailed description and the drawings.

According to the present disclosure, an anode electrode includes a side mirror (SM) structure so that a display device with an excellent luminous efficiency may be provided.

According to the present disclosure, capping layers having a low refractive index and a high refractive index are alternately laminated to compensate for the luminous efficiency by additionally increasing the reflectance. By doing this, the low power may be implemented.

According to the present disclosure, different thicknesses of organic layers are applied to individual sub pixels to improve the luminous efficiency and improve the viewing angle.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a diagram exemplarily illustrating a display device according to the present disclosure;

FIG. 2 is a plan view schematically illustrating a display device according to the present disclosure;

FIG. 3 is an equivalent circuit of a sub pixel of a display device according to the present disclosure;

FIG. 4 is a view illustrating a cross-sectional structure of a display panel according to a first exemplary embodiment of the present disclosure;

FIG. 5A is a perspective view exemplarily illustrating a first open area of a third planarization layer in a sub pixel structure of FIG. 4;

FIG. 5B is a perspective view exemplarily illustrating a second open area of a bank in a sub pixel structure of FIG. 4;

FIG. 6 is a view exemplarily illustrating an emission image according to a first exemplary embodiment of the present disclosure;

FIG. 7 is a cross-sectional view illustrating a pixel structure of a first exemplary embodiment of the present disclosure;

FIG. 8 is a cross-sectional view illustrating a pixel structure of a second exemplary embodiment of the present disclosure;

FIG. 9 is a table for comparing a luminous efficiency;

FIGS. 10A to 10D are graphs illustrating changes in visibility;

FIGS. 11A to 11F are views sequentially illustrating a manufacturing process of a display panel illustrated in FIG. 8; and

FIG. 12 is a cross-sectional view illustrating a pixel structure of a third exemplary embodiment of the present disclosure.

### DETAILED DESCRIPTION

Advantages and characteristics of the present disclosure and a method of achieving the advantages and characteristics will be clear by referring exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

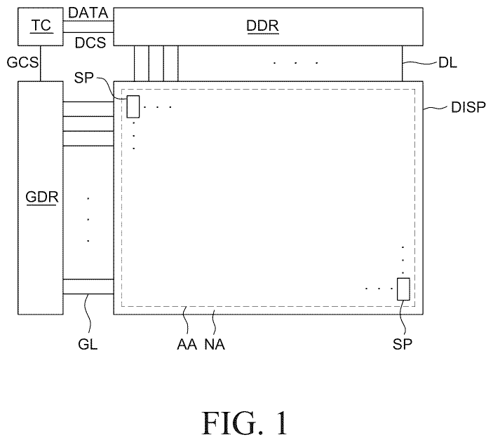

FIG. 1 is a diagram exemplarily illustrating a display device according to the present disclosure.

A display device according to exemplary embodiments of the present disclosure may include a display device, an illumination device, and an electroluminescent display device. Hereinafter, for the convenience of description, the display device will be mainly described. However, the following description will be applied to other various display devices, such as an illumination device or an electroluminescent display device, in the same way.

Referring to FIG. 1, the display device according to the exemplary embodiments of the present disclosure may include a display panel DISP which displays an image or outputs light and a driving circuit which drives the display panel DISP.

In the display panel DISP, a plurality of data lines DL and a plurality of gate lines GL are disposed and a plurality of sub pixels SP defined by the plurality of data lines DL and the plurality of gate lines GL may be disposed in a matrix.

The plurality of data lines DL and the plurality of gate lines GL of the display panel DISP may intersect each other. For example, the plurality of gate lines GL may be disposed in the unit of rows or columns and the plurality of data lines DL may be disposed in the unit of columns or rows. Hereinafter, for the convenience of description, it is assumed that the plurality of gate lines GL is disposed in rows and the plurality of data lines DL is disposed in columns.

In the display panel DISP, according to a sub pixel structure, other types of signal lines may be disposed, other than the plurality of data lines DL and the plurality of gate lines GL. For example, a driving voltage line, a reference voltage line, or a common voltage line may be further disposed.

The display panel DISP may be various types of panels, such as a liquid crystal display (LCD) panel or an organic light emitting diode (OLED) panel.

A type of signal lines disposed in the display panel DISP may vary depending on a sub pixel structure or a panel type. Further, in the present disclosure, a signal line may also be a concept including an electrode to which a signal is applied.

The display panel DISP may include an active area AA in which images are displayed and a non-active area NA which is an outer periphery of the active area AA and does not display images. Here, the non-active area NA is also referred to as a bezel area.

In the active area AA, a plurality of sub pixels SP may be disposed to display images.

In the non-active area NA, a pad unit to which a data driver DDR is electrically connected is disposed and a plurality of data link lines may also be disposed to connect the pad unit and the plurality of data lines DL. Here, the plurality of data link lines are parts formed by extending the plurality of data lines DL to the non-active area NA or separate patterns which are electrically connected to the plurality of data lines DL.

Further, in the non-active area NA, gate driving related lines for transmitting a voltage required to the gate driving to the gate driver GDR through the pad unit to which the above-described data driver DDR is electrically connected may be disposed. For example, the gate driving related lines may include a clock line which transmits a clock signal, a gate voltage line which transmits gate voltages VGH and VGL, and a gate driving control signal which transmits various control signals required to generate a scan signal. Such gate driving related lines may be disposed in the non-active area NA, unlike the gate line GL which is disposed in the active area AA.

For example, the driving circuit may include a data driver DDR which drives the plurality of data lines DL, a gate driver GDR which drives the plurality of gate lines GL, and a timing controller TR which controls the data driver DDR and the gate driver GDR.

As described above, the data driver DDR may output a data voltage to the plurality of data lines DL to drive the plurality of data lines DL.

Further, the gate driver GDR outputs the scan signal to the plurality of gate lines GL to drive the plurality of gate lines GL.

For example, the timing controller TR supplies various control signals DCS and GCS required for the driving operations of the data driver DDR and the gate driver GDR to control the driving operations of the data driver DDR and the gate driver GDR. Further, the timing controller TR may supply image data DATA to the data driver DDR.

The timing controller TR starts scanning according to a timing implemented in each frame, converts input image data input from the outside to be suitable for a data signal form used by the data driver DDR to output the converted image data DATA, and controls data driving at a proper time in accordance with the scanning.

For example, the timing controller TR receives timing signals, such as a vertical synchronization signal Vsync, a horizontal synchronization signal Hsync, an input data enable (DE) signal, and a clock signal CLK, from the outside to DDR and the gate driver GDR to control the data driver generate various control signals. The timing controller may output the generated various control signals to the data driver DDR and the gate driver GDR.

For example, in order to control the gate driver GDR, the timing controller TR may output various gate control signals GCS including a gate start pulse GSP, a gate shift clock GSC, and a gate output enable GOE signal.

Further, in order to control the data driver DDR, the timing controller TR may output various data control signals DCS including a source start pulse SSP, a source sampling clock SSC, and a source output enable SOE signal.

The timing controller TR may be implemented as a component separated from the data driver DDR or may be integrated with the data driver DDR to be implemented as an integrated circuit.

The data driver DDR receives image data DATA from the timing controller TR to supply a data voltage to the plurality of data lines DL to drive the plurality of data lines DL. The data driver DDR is also referred to as a source driver.

The data driver DDR may exchange various signals with the timing controller TR through various interfaces.

Further, the gate driver GDR sequentially supplies the scan signal to the plurality of gate lines GL to sequentially drive the plurality of gate lines GL. Here, the gate driver GDR is also referred to as a scan driver.

The gate driver GDR may sequentially supply a scan signal of an on-voltage or an off-voltage to the plurality of gate lines GL in accordance with the control of the timing controller TR.

When a specific gate line is open by the gate driver GDR, the data driver DDR converts image data DATA received from the timing controller TR into a data voltage in analog form to supply the converted data voltage in analog form to the plurality of data lines DL.

The data driver DDR may also be disposed on only one side of the display panel DISP or in some cases, may be disposed on both sides of the display panel DISP according to a driving method and a panel design method. For example, the data driver DDR may also be disposed above or below the display panel DISP or disposed both above and below the display panel DISP.

The gate driver GDR may also be disposed only one side of the display panel DISP or in some cases, may be disposed on both sides of the display panel DISP according to a driving method and a panel design method. For example, the gate driver GDR may also be disposed in a left side or a right side of the display panel DISP or disposed in both the left side and the right side of the display panel DISP.

The data driver DDR may be implemented to include one or more source driver integrated circuits (SDIC).

For example, each source driver integrated circuit may include a shift register, a latch circuit, a digital to analog converter (DAC), or an output buffer. The data driver DDR, in some cases, may further include one or more analog to digital converters (ADC).

Further, each source driver integrated circuit may be connected to a bonding pad of the display panel DISP as a tape automated bonding (TAB) type or a chip on glass (COG) type or may also be disposed directly on the display panel DISP. In some cases, each source driver integrated circuit may also be integrated in the display panel DISP. Further, each source driver integrated circuit may also be implemented as a chip on film (COF) type. In this case, each source driver integrated circuit is mounted on a circuit film to be electrically connected to the data line DL in the display panel DISP through the circuit film.

The gate driver GDR may also be configured by a plurality of gate driving circuits. Here, the plurality of gate driving circuits may correspond to each of the plurality of gate lines GL.

For example, each gate driving circuit may include a shift register and a level shifter.

The gate driving circuit may be connected to the bonding pad of the display panel DISP as a tape automated bonding (TAB) type or a chip on glass (COG) type. Further, each gate driving circuit may also be implemented as a chip on film (COF) type. In this case, each gate driving circuit is mounted on a circuit film to be electrically connected to the gate line GL in the display panel DISP through the circuit film. Further, each gate driver circuit is implemented as a gate in panel (GIP) type to be embedded in the display panel DISP. For example, each gate driving circuit may be directly formed in the display panel DISP.

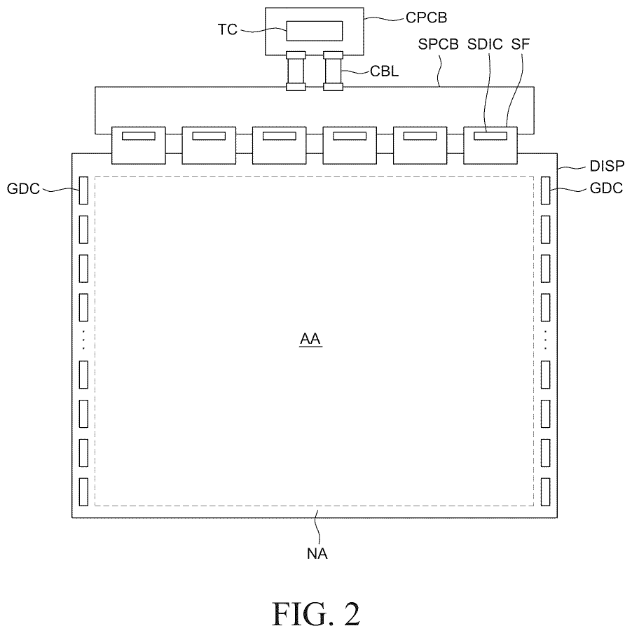

FIG. 2 is a plan view schematically illustrating a display device according to the present disclosure.

Referring to FIG. 2, in the display device according to exemplary embodiments of the present disclosure, the data driver is implemented as a chip on film (COF) type, among the above-described various types TAB, COG, and COF and the gate driver may be implemented as a gate in panel (GIP) type, among various types TAB, COG, COF, and GIP. However, it is not limited thereto and may be implemented as various types.

The data driver may be implemented by one or more source driver integrated circuits (SDIC). FIG. 2 illustrates that the data driver is implemented by a plurality of source driver integrated circuits (SDIC), but is not limited thereto.

When the data driver is implemented as a COF type, each source driver integrated circuit (SDIC) which implements a data driver may be mounted on the source-side circuit film SF.

For example, one side of the source-side circuit film SF is electrically connected to a pad unit (an assembly of pads) disposed in the non-active area NA of the display panel DISP.

Further, wiring lines which electrically connect the source driver integrated circuit SDIC and the display panel DISP may be disposed on the source-side circuit film SF.

The display device may include one or more source printed circuit boards SPCB and a control printed circuit board CPCB for mounting control components and various electric devices, for circuit connections between the plurality of source driver integrated circuits SDIC and the other devices.

For example, the other side of the source-side circuit film SF in which the source driver integrated circuit SDIC is mounted may be connected to one or more source printed circuit boards SPCB. For example, one side of the source-side circuit film SF in which the source driver integrated circuit SDIC is mounted is electrically connected to the non-active area NA of the display panel DISP and the other side may be electrically connected to the source printed circuit board SPCB.

Further, in the control printed circuit board CPCB, a timing controller TC which controls the operations of the data driver and the gate driver GDR may be disposed.

In the control printed circuit board CPCB, a power management IC (PMIC) which supplies various voltages or currents to the display panel DISP, the data driver, and the gate driver or controls various voltages or currents to be supplied may also be further disposed.

The source printed circuit board SPCB and the control printed circuit board CPCB may be electrically connected through at least one connection member CBL.

For example, the connection member CBL may be a flexible printed circuit (FPC) or a flexible flat cable (FFC).

For example, one or more source printed circuit boards SPCB and the control printed circuit board CPCB may also be integrated as one printed circuit board.

When the gate driver is implemented as a gate in panel (GIP) type, the plurality of gate driving circuits GDC included in the gate driver may be directly formed on the non-active area NA of the display panel DISP.

Each gate driving circuit GDC may output the scan signal to a corresponding gate line disposed in the active area AA in the display panel DISP.

The plurality of gate driving circuits GDC disposed on the display panel DISP may be supplied with various signals (a clock signal, a high level gate voltage VGH, a low level gate voltage VGL, a start signal VST, and a reset signal RST) required to generate the scan signal through gate driving related lines disposed in the non-active area NA.

The gate driving related lines disposed in the non-active area NA may be electrically connected to the source-side circuit film SF which is the most adjacent to the plurality of gate driving circuits GDC.

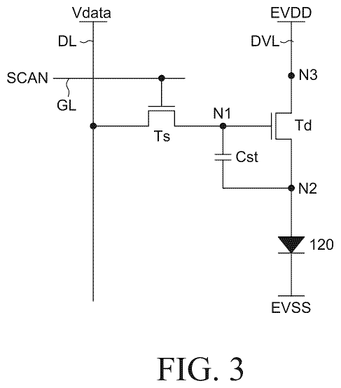

FIG. 3 is an equivalent circuit according to a sub pixel of a display device according to the present disclosure.

FIG. 3 is an equivalent circuit according to one sub pixel when a display panel according to exemplary embodiments of the present disclosure is an electroluminescent display panel.

Referring to FIG. 3, each sub pixel includes a light emitting diode 120, a driving transistor Td which drives the light emitting diode 120, a switching transistor Ts which is electrically connected between a first node N1 of the driving transistor Td and the corresponding data line DL, and a storage capacitor Cst to be implemented. The storage capacitor Cst is electrically connected between the first node N1 and a second node N2 of the driving transistor Ts.

For example, the light emitting diode 120 may be configured by an anode electrode, a plurality of organic layers, and a cathode electrode.

Referring to FIG. 3, the anode electrode (also referred to as a pixel electrode) of the light emitting diode 120 may be electrically connected to the second node N2 of the driving transistor Td. In this case, a base voltage EVSS may be applied to the cathode electrode (also referred to as a common electrode) of the light emitting diode 120.

The base voltage EVSS may be a ground voltage or a voltage higher than or lower than the ground voltage. Further, the base voltage EVSS may vary depending on a driving state. For example, a base voltage EVSS during the image driving and a base voltage EVSS during sensing driving may be set to be different from each other.

The driving transistor Td supplies a driving current to the light emitting diode 120 to drive the light emitting diode 120.

The driving transistor Td may include a first node N1, a second node N2, and a third node N3.

The first node N1 of the driving transistor Td may be a gate node and may be electrically connected to a source node or a drain node of the switching transistor Ts. The second node N2 of the driving transistor Td may be a source node or a drain node and may be electrically connected to an anode electrode (or a cathode electrode) of the light emitting diode 120.

The third node N3 of the driving transistor Td may be a drain node or a source node, may be applied with a driving voltage EVDD, and may be electrically connected to a driving voltage line DVL which supplies the driving voltage EVDD.

The storage capacitor Cst is electrically connected between the first node N1 and the second node N2 of the driving transistor Td to maintain a data voltage Vdata corresponding to an image signal voltage or a voltage corresponding thereto for one frame time (or a predetermined time).

The drain node or the source node of the switching transistor Ts is electrically connected to a corresponding data line DL and the source node or the drain node of the switching transistor Ts may be electrically connected to the first node N1 of the driving transistor Td. Further, the gate node of the switching transistor Ts is electrically connected to the corresponding gate line to be applied with a scan signal SCAN.

The switching transistor Ts is applied with the scan signal SCAN through the corresponding gate node by means of the gate line to be controlled to be turned on or off.

The switching transistor Ts is turned on by the scan signal SCAN to transmit a data voltage Vdata supplied from the corresponding data line DL to the first node N1 of the driving transistor Td.

In the meantime, the storage capacitor Cst may be an external capacitor which is intentionally designed at the outside of the driving transistor Td, rather than a parasitic capacitor which is an internal capacitor present between the first node N1 and the second node N2 of the driving transistor Td.

For example, each of the driving transistor Td and the switching transistor Ts may be an n-type transistor or a p-type transistor.

Each sub pixel structure illustrated in FIG. 3 is a 2T (transistor) 1C (capacitor) structure, but this is just illustrative, so that the sub pixel structure may further include one or more transistors and in some cases, further include one or more capacitors. Alternatively, each of the plurality of sub pixels may also have the same structure or some of the plurality of sub pixels may also have a different structure.

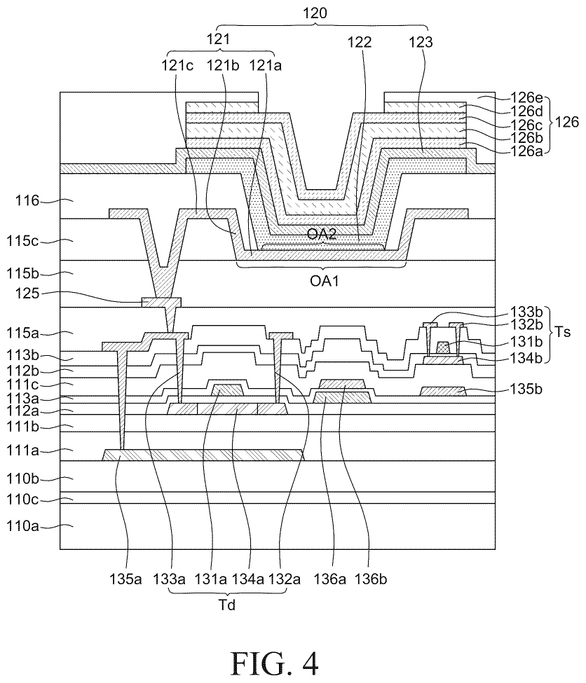

FIG. 4 is a view illustrating a cross-sectional structure of a display panel according to a first exemplary embodiment of the present disclosure.

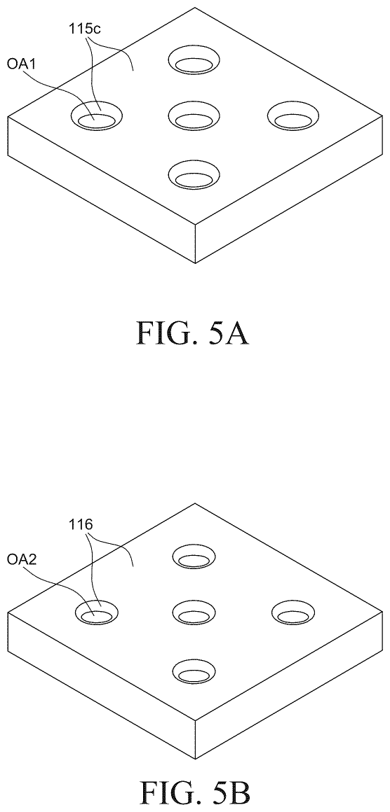

FIG. 5A is a perspective view exemplarily illustrating a first open area of a third planarization layer in a sub pixel structure of FIG. 4.

FIG. 5B is a perspective view exemplarily illustrating a second open area of a bank in a sub pixel structure of FIG. 4.

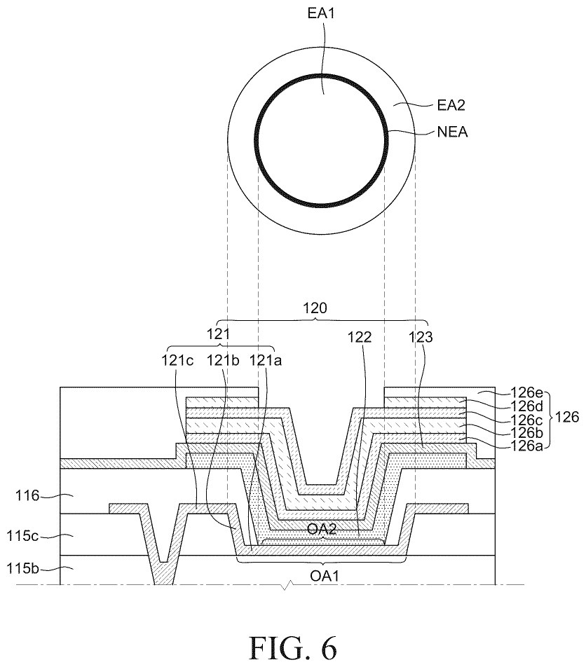

FIG. 6 is a view exemplarily illustrating an emission image according to a first exemplary embodiment of the present disclosure.

FIG. 4 illustrates a part of a cross section of one sub pixel of a display panel according to the first exemplary embodiment of the present disclosure.

Even though in FIG. 4, components above the light emitting diodes 120 are not illustrated for the convenience of description, the present disclosure is not limited thereto and the present disclosure may include an encapsulation layer and a touch sensor layer above the light emitting diode 120.

FIGS. 5A and 5B illustrate a first open area OA1 of a third planarization layer 115c and a second open area OA2 of the bank 116 included in the display panel according to the first exemplary embodiment of the present disclosure as an example.

FIG. 6 exemplarily illustrates a part of a cross-sectional structure of a sub pixel illustrated in FIG. 4 and an emission image corresponding thereto.

Referring to FIGS. 4 to 6, a driving transistor Td, a switching transistor Ts, and a light emitting diode 120 may be disposed above substrates 110a, 110b, and 110c.

For example, the substrates 110a, 110b, and 110c may include a first substrate 110a, a second substrate 110b, and an interlayer insulating film 110c. The interlayer insulating film 110c may be disposed between the first substrate 110a and the second substrate 110b.

As described above, the substrates 110a, 110b, and 110c are configured with a first substrate 110a, a second substrate 110c to suppress 110b, and an interlayer permeation of the moisture. For example, the first substrate 110a and the second substrate 110b may be configured with polyimide (PI).

Transistors, such as a driving transistor Td or a switching transistor Ts may be disposed above the substrates 110a, 110b, and 110c.

A multi-buffer layer 111a may be disposed on the second substrate 110b and an active buffer layer 111b may be disposed on the multi-buffer layer 111a.

A first light shielding layer 135a may be disposed above the second substrate 110b. However, it is not limited thereto and the first light shielding layer 135a may also be disposed on the multi-buffer layer 111a.

The first light shielding layer 135a may serve to shield light.

The multi-buffer layer 111a may be disposed on the first light shielding layer 135a.

The active buffer layer 111b may be disposed on the multi-buffer layer 111a.

A first active layer 134a of the driving transistor Td may be disposed above the active buffer layer 111b.

A first gate insulating film 112a may be disposed on the first active layer 134a.

Further, a first gate electrode 131a of the driving transistor Td may be disposed on the first gate insulating film 112a.

Further, for example, a gate material layer 136a may also be disposed on the first gate insulating film 112a in a position different from a forming position of the driving transistor Td. For example, the gate material layer 136a may be a first storage electrode, but is not limited thereto.

The first interlayer insulating film 113a may be disposed on the first gate electrode 131a.

A metal layer 136b may be disposed on the first interlayer insulating film 113a. For example, the material layer 136b may be a second storage electrode, but is not limited thereto.

In this case, the metal layer 136b may configure the storage capacitor together with the gate material layer 136a, but is not limited thereto.

Further, for example, a second light shielding layer 135b may be disposed on the first interlayer insulating film 113a in a position different from a forming position of the metal layer 136b.

The buffer layer 111c may be disposed on the metal layer 136b and the second light shielding layer 135b.

A second active layer 134b of the switching transistor Ts may be disposed on the buffer layer 111c.

A second gate insulating film 112b may be disposed on the second active layer 134b.

Further, a second gate electrode 131b of the switching transistor Ts may be disposed on the second gate insulating film 112b.

The second interlayer insulating film 113b may be disposed on the second gate electrode 131b.

A first source electrode 132a and a first drain electrode 133a of the driving transistor Td may be disposed on the second interlayer insulating film 113b. Further, a second source electrode 132b and a second drain electrode 133b of the switching transistor Ts may be disposed on the second interlayer insulating film 113b.

For example, the first source electrode 132a and the first drain electrode 133a may be electrically connected to each one side and the other side of the first active layer 134a through contact holes provided in the second interlayer insulating film 113b, the second gate insulating film 112b, the buffer layer 111c, the first interlayer insulating film 113a, and the first gate insulating film 112a.

For example, a part of the first drain electrode 133a may be electrically connected to one side of the first shielding layer 135a through contact holes provided in the second interlayer insulating film 113b, the second gate insulating film 112b, the buffer layer 111c, the first interlayer insulating film 113a, the first gate insulating film 112a, the active buffer layer 111b, and the multi-buffer layer 111a.

Further, for example, the second source electrode 132b and the second drain electrode 133b may be electrically connected to one side and the other side of the second active layer 134b, through contact holes provided in the second interlayer insulating film 113b and the second gate insulating film 112b, respectively.

A part of the first active layer 134a which overlaps the first gate electrode 131a is a channel region. For example, one of the first source electrode 132a and the first drain electrode 133a is electrically connected to one side of the channel region in the first active layer 134a and the other one may be electrically connected to the other side of the channel region in the first active layer 134a.

Further, a part of the second active layer 134b which overlaps the second gate electrode 131b is a channel region. For example, one of the second source electrode 132b and the second drain electrode 133b is electrically connected to one side of the channel region in the second active layer 134b and the other one may be electrically connected to the other side of the channel region in the second active layer 134b.

Even though it is not illustrated, a passivation film may be disposed on the first source electrode 132a, the first drain electrode 133a, the second source electrode 132b, and the second drain electrode 133b.

The planarization layers 115a and 115b may be disposed above the first source electrode 132a, and the first drain electrode 133a and the second source electrode 132b and the second drain electrode 133b. For example, the planarization layers 115a and 115b may include a first planarization layer 115a and a second planarization layer 115b, but are not limited thereto.

The first planarization layer 115a may be disposed on the passivation film.

The connection electrode 125 may be disposed on the first planarization layer 115a.

For example, the connection electrode 125 may be electrically connected to one of the first source electrode 132a and the first drain electrode 133a through a contact hole provided in the first planarization layer 115a.

The second planarization layer 115b may be disposed on the connection electrode 125.

A third planarization layer 115c may be disposed on the second planarization layer 115b.

The third planarization layer 115c may be configured by an organic material, such as acrylic resin or epoxy resin, and for example, may be configured by photo acryl (PAC). The third planarization layer 115c may also be referred to as a bank.

For example, the third planarization layer 115c may include a first open area OA1 obtained by removing (opening) a part corresponding to a main emission area EA1, a reflective emission area EA2, and a non-emission area NEA of the sub pixel.

For example, in the plan view, the first open area OA1 may have an approximately circular shape (see FIG. 5A), but is not limited thereto. For example, the first open area OA1 may have various shapes such as an oval shape or a rectangular shape in the plan view.

The third planarization layer 115c may include a top surface and a side portion.

The top surface of the third planarization layer 115c is a surface located at the top of the third planarization layer 115c and may be substantially parallel to the second substrate 110b.

The side portion of the third planarization layer 115c may be a surface extending from the top surface of the third planarization layer 115c to a side surface. For example, a side portion of the third planarization layer 115c may have a predetermined taper angle. For example, the side portion of the third planarization layer 115c may have a taper angle of 30° to 65°, but is not limited thereto.

In the plan view, the side portion of the third planarization layer 115c may have an approximately circular shape (see FIG. 5A), like the edge of the first open area OA1, but is not limited thereto. The side portion of the third planarization layer 115c of the present disclosure may have various shapes such as an oval shape or a rectangular shape in the plan view.

For example, the anode electrode 121 may be disposed on the top surface and the side portion of the third planarization layer 115c and the top surface of the second planarization layer 115b. For example, the anode electrode 121 may be disposed on the first open area OA1 and the top surface and the side portion of the third planarization layer 115c.

For example, the anode electrode 121 which is disposed in the first open area OA1 may be in contact with the top surface of the second planarization layer 115b.

For example, the anode electrode 121 may include a first area 121a which has a surface substantially parallel to a surface of the second substrate 110b in the first open area OA1 and a second area 121b which extends from the first area 121a so that a surface has a predetermined angle with respect to the second substrate 110b. Further, for example, the first area 121a of the anode electrode 121 may correspond to the first open area OA1. For example, the second area 121b of the anode electrode 121 may correspond to a side portion of the third planarization layer 115c. Therefore, the second area 121b of the anode electrode 121 may also be referred to as a side portion of the anode electrode 121.

In the present disclosure, the second area 121b of the anode electrode 121 is a part having a side-mirror (SM) shape and may configure the SM structure. The SM structure of the anode electrode 121 may be configured in the first open area OA1. For example, the SM structure of the anode electrode 121 may form a reflective emission area EA2. For example, the reflective emission area EA2 follows an outline of the main emission area EA1 and may have a continuous ring shape or a ring shape with a break. In the case of the ring shape with a break, the reflective emission area may enclose the outline of the main emission area EA1 and have breaks in the middle.

According to the first exemplary embodiment of the present disclosure, the side portion of the third planarization layer 115c has an approximately circular shape so that the second area 121b of the anode electrode 121 deposited thereon may also have an approximately circular shape.

As described above, the SM structure configured in the first open area OA1 forms the reflective emission area EA2. A part of light emitted by the light emitting diode 120 is reflected from the second area 121b of the anode electrode 121 by the SM structure to form a ring-shaped reflective emission area EA2. Therefore, the luminous efficiency may be improved.

When the SM structure of the present disclosure is not applied, there is only one main emission area EA1. However, when the SM structure of the present disclosure is applied, it is understood that a reflective emission area EA2 by the SM structure is provided in the vicinity of the main emission area EA1 (see FIG. 6).

For example, in the case of the first exemplary embodiment of the present disclosure, the main emission area EA1 may have an approximately circular shape and the non-emission area NEA may have an approximately circular ring shape enclosing the main emission area EA1. Further, for example, the reflective emission area EA2 may also have an approximately circular ring shape.

Referring to FIGS. 4 to 6, the anode electrode 121 may include a third area 121c which extends from the second area 121b so that a surface is substantially parallel to a surface of the second substrate 110b. The third area 121c may correspond to the top surface of the third planarization layer 115c.

As described above, in one sub pixel, the second planarization layer 115b and the third planarization layer 115c may include at least one contact hole spaced apart from the first open area OA1. Therefore, the driving transistor Td and the anode electrode 121 of the light emitting diode 120 may be electrically connected through a contact hole.

The bank 116 may be disposed to cover the anode electrode 121.

The bank 116 may cover the second area 121b and the third area 121c of the anode electrode 121. Further, the bank 116 may cover a part of the first area 121a of the anode electrode 121. For example, the bank 116 may cover a part of the edge of the first area 121a of the anode electrode 121.

A part of the bank 116 corresponding to the main emission area EA1 may be open.

For example, the bank 116 may include a second open area OA2 obtained by removing (opening) a part corresponding to the main emission area EA1 of each sub pixel. For example, the first open area OA1 may be wider than the second open area OA2. For example, in the plan view, the second open area OA2 may have an approximately circular shape (see FIG. 5A), but is not limited thereto. The edge of the second open area OA2 of the present disclosure may have various shapes, such as an oval shape or a rectangular shape.

In the meantime, the main emission area EA1 may have a shape corresponding to a shape of the second open area OA2. When a shape of an arbitrary component corresponds to a shape of the other component, it may mean that the shape of the arbitrary component has the same shape as the other component, or has the same shape, but has a different size, or a shape of the arbitrary component is formed by transferring the shape of the other component by an arbitrary method. Accordingly, the shape of the main emission area EA1 is substantially understood to be obtained by transferring a shape of the second open area OA2 by light emitted from the organic layer 122 located in the second open area OA2.

The reflective emission area EA2 does not overlap the main emission area EA1 and may be located while enclosing the main emission area EA1.

Further, the reflective emission area EA2 may be a closed curve which encloses the main emission area EA1. Alternatively, the reflective emission area EA2 may have a shape of the closed curve which partially has a break.

The sub pixels may be divided by the main emission area EA1.

Next, the bank 116 may include a top surface, a side portion, and a bottom surface.

For example, the top surface of the bank 116 is a surface located at the top of the bank 116 and may be substantially parallel to the second substrate 110b. Further, the top surface of the bank 116 may correspond to the top surface of the third planarization layer 115c.

A side portion of the bank 116 may be a surface extending from the top surface of the bank 116 to a side surface. The side portion of the bank 116 may have a predetermined taper angle. For example, the side portion of the bank 116 may have a taper angle of 30° to 65°, but is not limited thereto. The side portion of the bank 116 may correspond to the side portion of the third planarization layer 115c.

For example, the bottom surface of the bank 116 may correspond to a surface which abuts with the anode electrode 121 in the first area 121a of the anode electrode 121. The bottom surface of the bank 116 may correspond to a non-emission area NEA between the main emission area EA1 and the reflective emission area EA1.

The first open area OA1 provided third planarization layer 115c may have a width larger than that of the second open area OA2 provided in the bank 116. Therefore, the second open area OA2 may be located in the first open area OA1.

For example, a part of the anode electrode 121 may be exposed by the second open area OA2.

The bank 116 may be formed of a PI based material, but is not limited thereto.

A side portion of the bank 116 may have the circular shape, like the edge of the second open area OA2 (see FIG. 5B), but the present disclosure is not limited thereto. For example, a side portion of the bank 116 of the present disclosure may have various shapes, such as an oval shape or a rectangular shape.

For example, the organic layer 122 may be disposed in the second open area OA2 of the bank 116 or in the vicinity thereof. For example, the organic layer 122 may be disposed on the anode electrode 121 exposed through the second open area OA2 of the bank 116. For example, the organic layer 122 may be disposed in the second open area OA2 of the bank 116.

The organic layer 122 may be disposed only in the second open area OA2, but the present disclosure is not limited thereto and a part thereof may also be disposed on a top surface and a side portion of the bank 116 other than the second open area OA2.

For example, the organic layer 122 may also be disposed on a part of the top surface and the side portion of the bank 116 so as to cover the third area 121c of the end of the anode electrode 121 in the second open area OA2 (see FIG. 6).

The organic layer 122 may include a hole injection layer (HIL), a hole transport layer (HTL), an emission layer (EML), an electron transport layer (ETL), and an electron injection layer (EIL), but is not limited thereto.

The cathode electrode 123 may be disposed on the organic layer 122.

As described above, the light emitting diode 120 may be configured by the anode electrode 121, the organic layer 122, and the cathode electrode 123.

For example, the main emission area EA1 may be formed by the light emitting diode 120 provided in the second open area OA2.

For example, the cathode electrode 121 may be commonly disposed in adjacent sub pixels.

According to the present disclosure, the anode electrode 121 may be configured to have a reflective characteristic. For example, in order to improve a color purity and a luminance of a front viewing angle of the light emitting diode 120, the anode electrode 121 is formed as a reflective electrode and the cathode electrode 123 may be formed as a transflective electrode to configure a micro cavity. The micro cavity refers to a structure which adjusts a distance between the reflective electrode (anode electrode 121) and the transflective electrode (cathode electrode 123) to have an optical distance which increases (constructive interference) of a brightness of a specific visible light wavelength band and reduces (destructive interference) of a brightness of another visible light wavelength band.

The reflective characteristic of the anode electrode 121 may be implemented using a metallic material (for example, silver (Ag) or APC) having a high reflectance of the visible light wavelength band, but is not limited thereto. The transflective characteristic of the cathode electrode 123 may be implemented using a metallic material (for example magnesium:silver (Mg:Ag) with a thickness of 150 Å to 250 Å) which is translucent with a transmittance of 35% to 45% in the visible light wavelength band when it is a thin film, but is not limited thereto.

The white light may refer to light in which red light, green light, and blue light are mixed. For example, the white light may be generated by applying an appropriate signal which may display white light to a red light emitting diode, a green light emitting diode, and a blue light emitting diode. For example, the white light may be generated by applying a red image signal, a green image signal, and a blue image signal with maximum gray scales to the red, green, and blue light emitting diodes, respectively, but it is not limited thereto.

As described above, according to the present disclosure, a micro cavity structure is applied to increase the light extraction efficiency. Further, in the present disclosure, the SM structure of the anode electrode 121 is applied to minimize a color variation according to the viewing angle for the front surface by the micro cavity structure. A top emission type display device uses the micro cavity effect to increase the front efficiency by means of the light extraction so that the luminance drop and the change in the visibility according to the viewing angle are inevitable. The SM structure may be applied to improve this problem, but improvements are needed to minimize the reduction in the front efficiency and the change in the visibility in the SM area.

A capping layer 126 may be disposed on the cathode electrode 123.

For example, the capping layer 126 may use any one material of host materials of emission layers which emit red light, green light, and blue light. Further, the capping layer 126 may use one or more materials selected from materials which form the hole transport layer and the electron transport layer, but is not limited thereto. For example, the capping layer 126 may use carbazole biphenyl (CBP) or mCP(1,3-bis(carbazol-9-yl).

Further, for example, the capping layer 126 may use one or more of LiF, Lio, MgF₂, NaF, Cao, KF, Bi₂S₃, NasAl₃F₁₄, and SiO₂.

The capping layer 126 of the first exemplary embodiment of the present disclosure may be configured by a plurality of layers.

For example, the capping layer 126 of the first exemplary embodiment of the present disclosure may be configured with a multi-layered structure of a first capping layer 126a having a first refractive index, a second capping layer 126b having a second refractive index, and a third capping layer 126c having a third refractive index.

The first capping layer 126a, the second capping layer 126b, and the third capping layer 126c according to the first exemplary embodiment of the present disclosure may be disposed on a part of the top surface and a side portion of the cathode electrode 123. For example, the first capping layer 126a, the second capping layer 126b, and the third capping layer 126c according to the first exemplary embodiment of the present disclosure may also be disposed on a part of the top surface and a side portion of the cathode electrode 123 so as to cover to the end of the organic layer 122 in the second open area OA2 (see FIG. 6). By doing this, the degradation of the efficiency due to the SM structure may be compensated.

For example, the second capping layer 126b may have a larger thickness than those of the first capping layer 126a and the third capping layer 126c. For example, the second capping layer 126b may have a thickness of approximately 700 Å and the first capping layer 126a and the third capping layer 126c may have a thickness of approximately 100 Å, but are not limited thereto.

Here, the thickness may refer to a thickness of each of the first capping layer 126a, the second capping layer 126b, and the third capping layer 126c disposed in the second open area OA2. Further, for example, thicknesses of the first capping layer 126a, the second capping layer 126b, and the third capping layer 126c disposed on a part of the top surface and the side portion of the cathode electrode 123 may be smaller than the thicknesses of the first capping layer 126a, the second capping layer 126b, and the third capping layer 126c disposed in the second open area OA2, but they are not limited thereto.

Further, the capping layer 126 according to the first exemplary embodiment of the present disclosure may further include a fourth capping layer 126d having a fourth refractive index disposed on the third capping layer 126c excluding the second open area OA2 and a fifth capping layer 126e having a fifth refractive index disposed on the fourth capping layer 126d excluding the second open area OA2. For example, the fourth capping layer 126d may be disposed only above the third area 121c of the anode electrode 121 excluding the second open area OA2 and the fifth capping layer 126e may extend to an adjacent sub pixel so as to cover the fourth capping layer 126d excluding the second open area OA2, but are not limited thereto. For example, the fifth capping layer 126e of the present disclosure may also partially extend to the second open area OA2 so as to cover a side surface of the fourth capping layer 126d. In this case, a part of the fifth capping layer 126e may be in contact with a top surface of the third capping layer 126c.

As described above, the fourth capping layer 126d and the fifth capping layer 126e are added only above the third area 121c of the anode electrode 121 to implement the optimization of the front efficiency. If the fourth capping layer 126d and the fifth capping layer 126e are also added to the second open area OA2, even though the luminous efficiency may be improved, the change in the visibility may be more significant in terms of the viewing angle.

The first refractive index, the third refractive index, and the fifth refractive index may be relatively lower than the second refractive index and the fourth refractive index. For example, the first refractive index, the third refractive index, and the fifth refractive index may be 1.5 or lower and the second refractive index and the fourth refractive index may be 1.8 or higher.

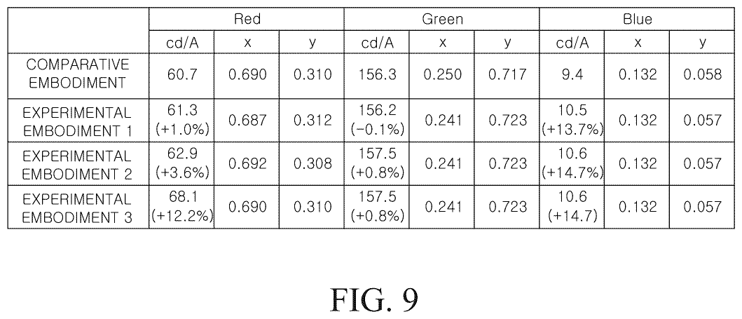

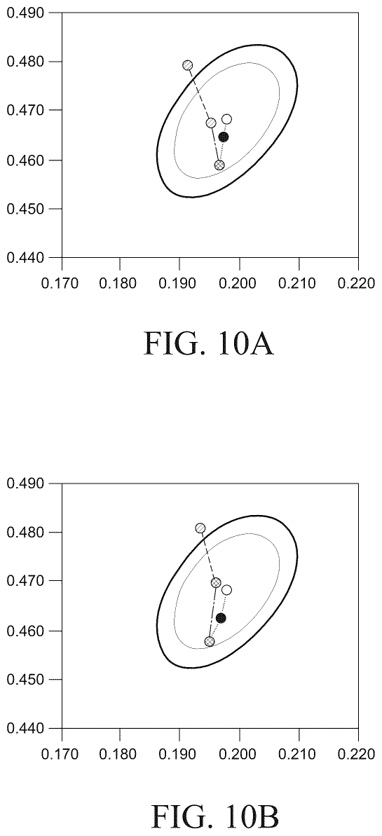

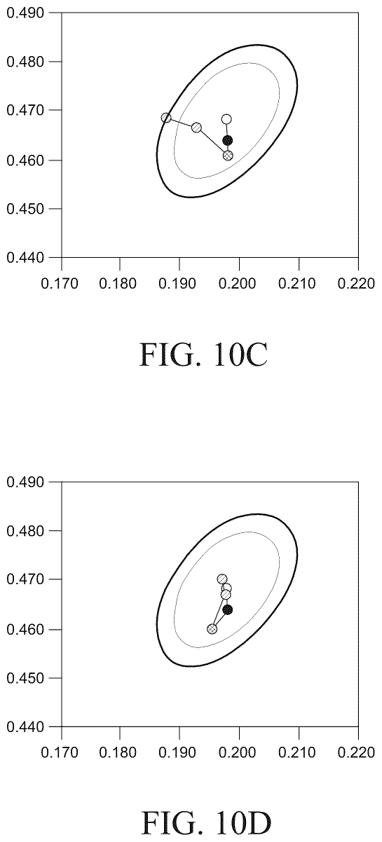

As described above, according to the present disclosure, the first capping layer 126a, the third capping layer 126c, and the fifth capping layer 126e having low refractive indexes and the second capping layer 126b and the fourth capping layer 126d having high refractive indexes are alternately laminated above the cathode electrode 123. By doing this, the front luminous efficiency may be compensated by additionally increasing the reflectance while maintaining the visibility. That is, a plurality of capping layers 126 having different refractive indexes is applied above the cathode electrode 123 so that surface plasmon loss caused by the cathode electrode 123 and the organic layer 122 therebelow is reduced to improve the front reflection. This will be described in detail with reference to FIGS. 9, and 10A to 10D.

An encapsulation layer may be disposed above the capping layer 126 configured as described above.

The encapsulation layer may have a single layer structure or a multi-layered structure.

For example, the encapsulation layer may include a first encapsulation layer, a second encapsulation layer, and a third encapsulation layer.

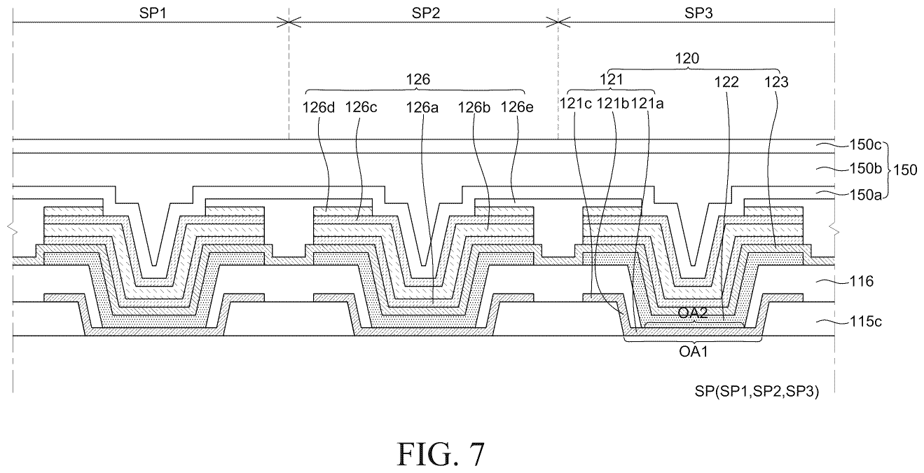

FIG. 7 is a cross-sectional view illustrating a pixel structure of a first exemplary embodiment of the present disclosure.

FIG. 7 illustrates a part of a cross-section of a display panel in which a plurality of sub pixels SP1, SP2, and SP3 of FIG. 4 described above is provided to configure one pixel SP. Therefore, the redundant description for the same configuration will be omitted.

FIG. 7 illustrates a part of the cross-section of a display panel in which three sub pixels SP1, SP2, and SP3 are disposed as an example. Further, in FIG. 7, for the convenience of description, configurations below the third planarization layer 115c are not illustrated.

Referring to FIG. 7, the display panel according to the first exemplary embodiment of the present disclosure may include a pixel area in which a plurality of sub pixels SP1, SP2, and SP3 is provided and a wiring area in which various signal lines are disposed.

A plurality of first sub pixels SP1, second sub pixels SP2, and third sub pixels SP3 may be disposed in the pixel area.

For example, the first sub pixel SP1 may be a red sub pixel.

For example, the second sub pixel SP2 may be a green sub pixel.

For example, the third sub pixel SP3 may be a blue sub pixel.

For example, the first sub pixel SP1, the second sub pixel SP2, and the third sub pixel SP3 may have a circular shape or a polygonal shape, but are not limited thereto. Here, a shape of the sub pixels SP1, SP2, and SP3 is defined by the shape of the anode electrode 121, but the present disclosure is not limited thereto.

In FIG. 7, it is illustrated that one first sub pixel SP1, one second sub pixel SP2, and one third sub pixel SP3 are gathered to configure one pixel SP, but is not limited thereto.

In the meantime, according to the present disclosure, due to the side mirror (SM) structure of the anode electrode 121, a reflective emission area is added as well as a main emission area so that the emission area may be expanded as compared with each of the sub pixels SP1, SP2, and SP3.

Referring to FIG. 7, the anode electrode 121 may be disposed on the third planarization layer 115c.

For example, the third planarization layer 115c may include a first open area OA1 obtained by removing (opening) a part corresponding to a main emission area of each of the sub pixels SP1, SP2, and SP3, a reflective emission area, and a non-emission area.

For example, in the plan view, the first open area OA1 may have an approximately circular shape, but is not limited thereto. For example, the first open area OA1 according to the present disclosure may have various shapes such as an oval shape or a rectangular shape in the plan view.

The third planarization layer 115c may include a top surface and a side portion.

The top surface of the third planarization layer 115c is a surface located at the top of the third planarization layer 115c and may be substantially parallel to the second substrate 110b.

The side portion of the third planarization layer 115c may be a surface extending from the top surface of the third planarization layer 115c to a side surface. For example, a side portion of the third planarization layer 115c may have a predetermined taper angle.

In the plan view, the side portion of the third planarization layer 115c may have an approximately circular shape, like the edge of the first open area OA1, but is not limited thereto. The side portion of the third planarization layer 115c of the present disclosure may have various shapes such as an oval shape or a rectangular shape in the plan view.

For example, the anode electrode 121 may be disposed on the top surface and the side portion of third planarization layer 115c and the top surface of the second planarization layer 115b. For example, the anode electrode 121 may be disposed on the first open area OA1 and the top surface and the side portion of the third planarization layer 115c.

For example, the anode electrode 121 which is disposed in the first open area OA1 may be in contact with the top surface of the second planarization layer 115b.

For example, the anode electrode 121 may include a first area 121a which has a surface substantially parallel to a surface of the second substrate 110b in the first open area OA1 and a second area 121b which extends from the first area 121a so that a surface has a predetermined angle with respect to the second substrate 110b. Further, for example, the first area 121a of the anode electrode 121 may correspond to the first open area OA1. For example, the second area 121b of the anode electrode 121 may correspond to a side portion of the third planarization layer 115c.

In the present disclosure, the second area 121b of the anode electrode 121 may configure the SM structure. The SM structure of the anode electrode 121 may be configured in the first open area OA1. For example, the SM structure of the anode electrode 121 may form a reflective emission area. For example, the reflective emission area follows an outline of the main emission area and may have a continuous ring shape or a ring shape with a break. In the case of the ring shape with a break, the reflective emission area may enclose the outline of the main emission area and have a break in the middle.

According to the first exemplary embodiment of the present disclosure, the side portion of the third planarization layer 115c has an approximately circular shape so that the second area 121b of the anode electrode 121 deposited thereon may also have an approximately circular shape.

As described above, the SM structure configured by the first open area OA1 forms the reflective emission area. A part of light emitted by the light emitting diode 120 is reflected from the second area 121b of the anode electrode 121 by the SM structure to form a ring-shaped reflective emission area. Therefore, the luminous efficiency may be improved.

Referring to FIG. 7, the anode 121 may include a third area 121c which extends from the second area 121b so that a surface is substantially parallel to a surface of the second substrate 110b. The third area 121c may correspond to the top surface of the third planarization layer 115c.

The bank 116 may be disposed to cover the anode electrode 121.

The bank 116 may cover the second area 121b and the third area 121c of the anode electrode 121. Further, the bank 116 may cover a part of the first area 121a of the anode electrode 121. For example, the bank 116 may cover a part of the edge of the first area 121a of the anode electrode 121.

A part of the bank 116 corresponding to the main emission area may be open.

For example, the bank 116 may include a second open area OA2 obtained by removing (opening) a part corresponding to the main emission area of each of the sub pixels SP1, SP2, and SP3. For example, the first open area OA1 may have wider than the second open area OA2. For example, in the plan view, the second open area OA2 may have an approximately circular shape, but is not limited thereto. The edge of the second open area OA2 of the present disclosure may have various shapes, such as an oval shape or a rectangular shape.

Next, the bank 116 may include a top surface, a side portion, and a bottom surface.

For example, the top surface of the bank 116 is a surface located at the top of the bank 116 and may be substantially parallel to the second substrate 110b. Further, the top surface of the bank 116 may correspond to the top surface of the third planarization layer 115c.

A side portion of the bank 116 may be a surface extending from the top surface of the bank 116 to a side surface. The side portion of the bank 116 may have a predetermined taper angle.

For example, the bottom surface of the bank 116 may correspond to a surface which abuts with the anode electrode 121 in the first area 121a of the anode electrode 121. The bottom surface of the bank 116 may correspond to a non-emission area NEA between the main emission area EA1 and the reflective emission area EA1.

For example, a part of the anode electrode 121 may be exposed by the second open area OA2.

A side portion of the bank 116 may have the circular shape, like the edge of the second open area OA2, but the present disclosure is not limited thereto. For example, a side portion of the bank 116 of the present disclosure may have various shapes, such as an oval shape or a rectangular shape.

For example, the organic layer 122 may be disposed in the second open area OA2 of the bank 116 and in the vicinity thereof. For example, the organic layer 122 may be disposed on the anode electrode 121 exposed through the second open area OA2 of the bank 116. For example, the organic layer 122 may be disposed in the second open area OA2 of the bank 116.

The organic layer 122 may be disposed only in the second open area OA2, but the present disclosure is not limited thereto and a part thereof may also be disposed on a top surface and a side portion of the bank 116 other than the second open area OA2.

For example, the organic layer 122 may also be disposed on a part of the top surface and the side portion of the bank 116 so as to cover the third area 121c of the end of the anode electrode 121 in the second open area OA2.

The cathode electrode 123 may be disposed on the organic layer 122.

For example, the cathode electrode 121 may be commonly disposed in adjacent sub pixels SP1, SP2, and SP3.

According to the present disclosure, the anode electrode 121 is formed as a reflective electrode and the cathode electrode 123 is formed as a transflective electrode to configure a micro cavity.

The reflection property of the anode electrode 121 may be implemented using a metallic material (for example, silver (Ag) or APC) having a high reflectance of the visible light wavelength band, but is not limited thereto. The transflective characteristic of the cathode electrode 123 may be implemented using a metallic material (for example magnesium:silver (Mg:Ag) with a thickness of 150 Å to 250 Å) which may be translucent with a transmittance of 35% to 45% in the visible light wavelength band when it is a thin film, but is not limited thereto.

The white light may refer to light in which red light, green light, and blue light are mixed. For example, the white light may be generated by applying an appropriate signal which may display white light to a red light emitting diode, a green light emitting diode, and a blue light emitting diode. For example, the white light may be generated by applying a red image signal, a green image signal, and a blue image signal with maximum gray scales to each of the red, green, and blue light emitting diodes, but it is not limited thereto.

A red organic emission layer may have a photoluminescence spectrum by a host and/or dopant material included in the red organic emission layer. A wavelength having the highest intensity in the photoluminescence spectrum of the red organic emission layer may be defined as a photoluminescence peak of the red organic emission layer.

A green organic emission layer may have a photoluminescence spectrum by a host and/or dopant material included in the green organic emission layer. A wavelength having the highest intensity in the photoluminescence spectrum of the green organic emission layer may be defined as a photoluminescence peak of the green organic emission layer.

A blue organic emission layer may have a photoluminescence spectrum by a host and/or dopant material included in the blue organic emission layer. A wavelength having the highest intensity in the photoluminescence spectrum of the blue organic emission layer may be defined as a photoluminescence peak of the blue organic emission layer.

Each light emitting diode may have an optical distance. For example, the optical distance of the red light emitting diode may be defined by a distance between a top surface of the anode electrode 121 and a bottom surface of the cathode electrode 123 in the first sub pixel SP1. For example, the optical distance of the green light emitting diode may be defined by a distance between a top surface of the anode electrode 121 and a bottom surface of the cathode electrode 123 in the second sub pixel SP2. For example, the optical distance of the blue light emitting diode may be defined by a distance between a top surface of the anode electrode 121 and a bottom surface of the cathode electrode 123 in the third sub pixel SP3.

Each optical distance may configure a micro cavity to amplify the photoluminescence peak wavelength of the corresponding organic emission layer.

The optical distance of each light emitting diode may be adjusted by at least one individual layer. For example, the optical distance of the first sub pixel SP1 may be adjusted by a hole transport layer of the first sub pixel SP1. For example, the optical distance of the second sub pixel SP2 may be adjusted by a hole transport layer of the second sub pixel SP2. For example, the optical distance of the third sub pixel SP3 may be adjusted by a hole transport layer of the third sub pixel SP3. However, the present disclosure is not limited thereto and the optical distance may be adjusted by at least another individual layer.

As described above, according to the present disclosure, a micro cavity structure is applied to increase the light extraction efficiency. Further, in the present disclosure, the SM structure of the anode electrode 121 is applied to minimize a color variation according to the viewing angle for the front surface.

A capping layer 126 may be disposed on the cathode electrode 123.

The capping layer 126 of the first exemplary embodiment of the present disclosure may be configured by a plurality of layers.

For example, the capping layer 126 of the first exemplary embodiment of the present disclosure may be configured with a multi-layered structure of a first capping layer 126a having a first refractive index, a second capping layer 126b having a second refractive index, and a third capping layer 126c having a third refractive index.

The first capping layer 126a, the second capping layer 126b, and the third capping layer 126c according to the first exemplary embodiment of the present disclosure may also be disposed on a part of the top surface and a side portion of the cathode electrode 123. For example, the first capping layer 126a, the second capping layer 126b, and the third capping layer 126c according to the first exemplary embodiment of the present disclosure may be disposed on a part of the top surface and a side portion of the cathode electrode 123 so as to cover to the end of the organic layer 122 in the second open area OA2. By doing this, the degradation of the efficiency due to the SM structure may be compensated.

For example, the second capping layer 126b may have a larger thickness than those of the first capping layer 126a and the third capping layer 126c. For example, the second capping layer 126b may have a thickness of approximately 700 Å and the first capping layer 126a and the third capping layer 126c may have a thickness of approximately 100 Å, but are not limited thereto.

Further, the capping layer 126 according to the first exemplary embodiment of the present disclosure may further include a fourth capping layer 126d having a fourth refractive index disposed on the third capping layer 126c excluding the second open area OA2 and a fifth capping layer 126e having a fifth refractive index disposed on the fourth capping layer 126d excluding the second open area OA2. For example, the fourth capping layer 126d may be disposed only above the third area 121c of the anode electrode 121 excluding the second open area OA2 and the fifth capping layer 126e may extend to an adjacent sub pixel so as to cover the fourth capping layer 126d excluding the second open area OA2, but are not limited thereto. For example, the fifth capping layer 126e of the present disclosure may also partially extend to the second open area OA2 so as to cover a side surface of the fourth capping layer 126d. In this case, a part of the fifth capping layer 126e may be in contact with a top surface of the third capping layer 126c.

As described above, the fourth capping layer 126d and the fifth capping layer 126e are added only above the third area 121c of the anode electrode 121 to implement the optimization of the front efficiency.

The first refractive index, the third refractive index, and the fifth refractive index may be lower than the second refractive index and the fourth refractive index. For example, the first index, the third refractive index, and the fifth refractive index may be 1.5 or lower and the second refractive index and the fourth refractive index may be 1.8 or higher.

As described above, according to the present disclosure, the first capping layer 126a, the third capping layer 126c, and the fifth capping layer 126e having low refractive indexes and the second capping layer 126b and the fourth capping layer 126d having high refractive indexes are alternately laminated above the cathode electrode 123. By doing this, the front luminous efficiency may be compensated by additionally increasing the reflectance while maintaining the visibility.

An encapsulation layer 150 may be disposed above the capping layer 126 configured as described above.

The encapsulation layer 150 may have a single layer structure or a multi-layered structure.

For example, the encapsulation layer 150 may include a first encapsulation layer 150a, a second encapsulation layer 150b, and a third encapsulation layer 150c.

For example, the first encapsulation layer 150a and the third encapsulation layer 150c are configured by inorganic films and the second encapsulation layer 150b may be configured by an organic film. For example, among the first encapsulation layer 150a, the second encapsulation layer 150b, and the third encapsulation layer 150c, the second encapsulation layer 150b is the thickest and may serve as a planarization layer.

The first encapsulation layer 150a may be formed by the inorganic insulating material which can be subjected to the low temperature deposition, and for example, may be configured by silicon nitride (SiNx), silicon oxide (SiOx), silicon oxynitride (SiON), or aluminum oxide (Al₂O₃).

The second encapsulation layer 150b may be formed to have a smaller area than that of the first encapsulation layer 150a. In this case, the second encapsulation layer 150b may be formed to expose both ends of the first encapsulation layer 150a.

For example, the second encapsulation layer 150b may be formed of an organic insulating material, such as acrylic resin, epoxy resin, polyimide, polyethylene, or silicon oxy carbon (SiOC). For example, the second encapsulation layer 150b may be formed by an inkjet method, but is not limited thereto.

The third encapsulation layer 150c may be formed to cover a top surface and a side surface of each of the second encapsulation layer 150b and the first encapsulation layer 150a.

At this time, the third encapsulation layer 150c may minimize or block the permeation of external moisture or oxygen into the first encapsulation layer 150a and the second encapsulation layer 150b. For example, the third encapsulation layer 150c may be configured by an inorganic insulating material, such as silicon oxide (SiOx), silicon oxynitride (SiON), aluminum oxide (Al₂O₃) or silicon nitride (SiNx).

A touch sensor layer may also be disposed above the above-described encapsulation layer 150.

In the meantime, when the SM structure is applied, the front efficiency may be reduced. However, different thicknesses of the capping layers are applied to individual sub pixels, the front efficiency may be improved while maintaining the visibility, which will be described in detail with reference to the drawing.

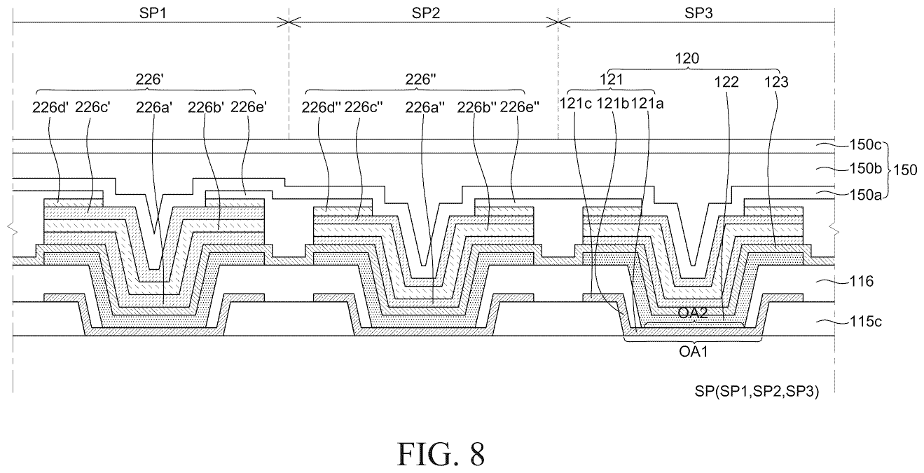

FIG. 8 is a cross-sectional view illustrating a pixel structure of a second exemplary embodiment of the present disclosure.

In a second exemplary embodiment of the present disclosure of FIG. 8, capping layers 226′ and 226″ have only different configurations from that of the first exemplary embodiment of the present disclosure of FIG. 7 described above, but other configurations are substantially the same so that a redundant description will be omitted.

FIG. 8 illustrates a part of the cross-section of a display panel in which three sub pixels SP1, SP2, and SP3 are disposed as an example. Further, in FIG. 8, for the convenience of description, configurations below the third planarization layer 115c are not illustrated.

Referring to FIG. 8, in the display panel according to the second exemplary embodiment of the present disclosure, a plurality of first sub pixels SP1, second sub pixels SP2, and third sub pixels SP3 may be disposed in the pixel area.

For example, the first sub pixel SP1 may be a red sub pixel.

For example, the second sub pixel SP2 may be a green sub pixel.

For example, the third sub pixel SP3 may be a blue sub pixel.

In FIG. 8, it is illustrated that one first sub pixel SP1, one second sub pixel SP2, and one third sub pixel SP3 are gathered to configure one pixel SP, but are not limited thereto.

Referring to FIG. 8, the anode electrode 121 may be disposed on the third planarization layer 115c.

For example, the third planarization layer 115c may include a first open area OA1 obtained by removing (opening) a part corresponding to a main emission area of each of the sub pixels SP1, SP2, and SP3, a reflective emission area, and a non-emission area.

The third planarization layer 115c may include a top surface and a side portion.

For example, the anode electrode 121 may be disposed on the top surface and the side portion of the third planarization layer 115c and the top surface of the second planarization layer 115b. For example, the anode electrode 121 may be disposed on the first open area OA1 and the top surface and the side portion of the third planarization layer 115c.

For example, the anode electrode 121 which is disposed in the first open area OA1 may be in contact with the top surface of the second planarization layer 115b.

For example, the anode electrode 121 may include a first area 121a which has a surface substantially parallel to a surface of the second substrate 110b in the first open area OA1 and a second area 121b which extends from the first area 121a so that a surface has a predetermined angle with respect to the second substrate 110b. Further, for example, the first area 121a of the anode electrode 121 may correspond to the first open area OA1. For example, the second area 121b of the anode electrode 121 may correspond to a side portion of the third planarization layer 115c.

In the present disclosure, the second area 121b of the anode electrode 121 may configure the SM structure. The SM structure of the anode electrode 121 may be configured in the first open area OA1. For example, the SM structure of the anode electrode 121 may form a reflective emission area.

Referring to FIG. 7, the anode electrode 121 may include a third area 121c which extends from the second area 121b so that a surface is substantially parallel to a surface of the second substrate 110b. The third area 121c may correspond to the top surface of the third planarization layer 115c.

The bank 116 may be disposed to cover the anode electrode 121.

The bank 116 may cover the second area 121b and the third area 121c of the anode electrode 121. Further, the bank 116 may cover a part of the first area 121a of the anode electrode 121. For example, the bank 116 may cover a part of the edge of the first area 121a of the anode electrode 121.

A part of the bank 116 corresponding to the main emission area may be open.

For example, the bank 116 may include a second open area OA2 obtained by removing (opening) a part corresponding to the main emission area of each of the sub pixels SP1, SP2, and SP3. For example, the first open area OA1 may be wider than the second open area OA2.

Next, the bank 116 may include a top surface, a side portion, and a bottom surface.

For example, the organic layer 122 may be disposed in the second open area OA2 of the bank 116 or in the vicinity thereof. For example, the organic layer 122 may be disposed on the anode electrode 121 exposed through the second open area OA2 of the bank 116. For example, the organic layer 122 may be disposed in the second open area OA2 of the bank 116.

The organic layer 122 may be disposed only in the second open area OA2, but the present disclosure is not limited thereto and a part thereof may also be disposed on a top surface and a side portion of the bank 116 other than the second open area OA2.

For example, the organic layer 122 may also be disposed on a part of the top surface and the side portion of the bank 116 so as to cover the third area 121c of the end of the anode electrode 121 in the second open area OA2.

The cathode electrode 123 may be disposed on the organic layer 122.

For example, the cathode electrode 123 may be commonly disposed in adjacent sub pixels SP1, SP2, and SP3.

According to the present disclosure, the anode electrode 121 is formed as a reflective electrode and the cathode electrode 123 may be formed as a transflective electrode to configure a micro cavity.

Each of the sub pixels SP1, SP2, and SP3 may have different optical distances from each other. A first optical distance of the first sub pixel SP1 is larger than a second optical distance of the second sub pixel SP2 and a third optical distance of the third sub pixel SP3 and the second optical distance of the second sub pixel SP2 may be larger than the third optical distance of the third sub pixel SP3.

Each optical distance may configure a micro cavity to amplify the photoluminescence peak wavelength of each corresponding organic emission layer.

The optical distance of each light emitting diode may be adjusted by at least one individual layer.

As described above, according to the present disclosure, a micro cavity structure is applied to increase the light extraction efficiency. Further, in the present disclosure, the SM structure of the anode electrode 121 is applied to minimize a color variation according to the viewing angle for the front surface.

Capping layers 226′ and 226″ may be disposed on the cathode electrode 123.

The capping layers 226′ and 226″ of the second exemplary embodiment of the present disclosure may include a first capping layer 226′ and a second capping layer 226″.

For example, the first capping layer 226′ may be disposed in the first sub pixel SP1 and the second capping layer 226″ may be disposed in the second sub pixel SP2 and the third sub pixel SP3, but are not limited thereto.

The capping layers 226′ and 226″ of the second exemplary embodiment of the present disclosure may be configured by a plurality of layers.

For example, the first capping layer 226′ of the second exemplary embodiment of the present disclosure may be configured with a multi-layered structure of a first-first capping layer 226a′ having a first refractive index, a first-second capping layer 226b′ having a second refractive index, and a first-third capping layer 226c′ having a third refractive index.

For example, the second capping layer 226″ of the second exemplary embodiment of the present disclosure may be configured with a multi-layered structure of a second-first capping layer 226a″ having a first refractive index, a second-second capping layer 226b″ having a second refractive index, and a second-third capping layer 226c″ having a third refractive index.

For example, the first-first capping layer 226a′, the first-second capping layer 226b′, and the first-third capping layer 226c′ may be disposed on a part of the top surface and a side portion of the cathode electrode 123. For example, the first-first capping layer 226a′, the first-second capping layer 226b′, and the first-third capping layer 226c′ may also be disposed on a part of the top surface and a side portion of the cathode electrode 123 so as to cover to the end of the organic layer 122 in the second open area OA2.

Further, for example, the second-first capping layer 226a″, the second-second capping layer 226b″, and the second-third capping layer 226c″ may be disposed on a part of the top surface and a side portion of the cathode electrode 123. For example, the second-first capping layer 226a″, the second-second capping layer 226b″, and the second-third capping layer 226c″ may be disposed on a part of the top surface and a side portion of the cathode electrode 123 so as to cover to the end of the organic layer 122 in the second open area OA2.

For example, the first-second capping layer 226b′ may be thicker than the first-first capping layer 226a′ and the first-third capping layer 226c′. For example, the first-second capping layer 226b′ may have a thickness of approximately 700 Å and the first-first capping layer 226a′ and the first-third capping layer 226c′ may have a thickness of approximately 200 Å, but the present disclosure is not limited thereto.

For example, the second-second capping layer 226b″ may be thicker than the second-first capping layer 226a″ and the second-third capping layer 226c″. For example, the second-second capping may thickness of layer 226b″ have a approximately 700 Å and the second-first capping layer 226a″ and the second-third capping layer 226c″ may have a thickness of approximately 100 Å, but the present disclosure is not limited thereto.

As described above, according to the second exemplary embodiment of the present disclosure, the first-first capping layer 226a′ and the first-third capping layer 226c′ may have a thickness approximately two times larger than the second-first capping layer 226a″ and the second-third capping layer 226c″. For example, a total thickness of the first capping layer 226′ of the first sub pixel SP1 which is the red sub pixel may be larger than a total thickness of the second capping layer 226″ of the second sub pixel SP2 which is a green sub pixel and the third sub pixel SP3 which is a blue sub pixel. As described above, only the total thickness of the first capping layer 226′ of the red sub pixel whose efficiency is proportional to the increase of the thickness is increased so that the front efficiency is increased while maintaining the visibility.

Further, the first capping layer 226′ according to the second exemplary embodiment of the present disclosure may further include a first-fourth capping layer 226d′ having a fourth refractive index disposed on the first-third capping layer 226c′ excluding the second open area OA2 and a first-fifth capping layer 226e′ having a fifth refractive index disposed on the first-fourth capping layer 226d′ excluding the second open area OA2. For example, the first-fourth capping layer 226d′ may be disposed only above the third area 121c of the anode electrode 121 excluding the second open area OA2 and the first-fifth capping layer 226e′ may extend to an adjacent sub pixel so as to cover the first-fourth capping layer 226d′ excluding the second open area OA2, but are not limited thereto. For example, the first-fifth capping layer 226e′ of the present disclosure may also partially extend to the second open area OA2 so as to cover a side surface of the first-fourth capping layer 226d′. At this time, a part of the first-fifth capping layer 226e′ may be in contact with the top surface of the first-third capping layer 226c′.

Further, the second capping layer 226″ according to the second exemplary embodiment of the present disclosure may further include a second-fourth capping layer 226d″ having a fourth refractive index disposed on the second-third capping layer 226c″ excluding the second open area OA2 and a second-fifth capping layer 226e″ having a fifth refractive index disposed on the second-fourth capping layer 226d″ excluding the second open area OA2. For example, the second-fourth capping layer 226d″ may be disposed only above the third area 121c of the anode electrode 121 excluding the second open area OA2 and the second-fifth capping layer 226e′ may extend to an adjacent sub pixel so as to cover the second-fourth capping layer 226d″ excluding the second open area OA2, but are not limited thereto. For example, the second-fifth capping layer 226e″ of the present disclosure may also partially extend to the second open area OA2 so as to cover a side surface of the second-fourth capping layer 226d″. At this time, a part of the second-fifth capping layer 226e″ may be in contact with the top surface of the second-third capping layer 226c″.

As described above, the first-fourth capping layer 226d′, the first-fifth capping layer 226e′, the second-fourth capping layer 226d″, and the second-fifth capping layer 226e″ are added only above the t third area 121c of the anode electrode 121 to implement the optimization of the front efficiency.

The first refractive index, the third refractive index, and the fifth refractive index may be relatively lower than the second refractive index and the fourth refractive index. For example, the first refractive index, the third refractive index, and the fifth refractive index may be 1.5 or lower and the second refractive index and the fourth refractive index may be 1.8 or higher.

As described above, according to the present disclosure, the first-first capping layer 226a′ and the second-first capping layer 226a′, the first-third capping layer 226c′ and the second-third capping layer 226c″, the first-fifth capping layer 226e′ and the second-fifth capping layer 226e″ having low refractive indexes and the first-second capping layer 226b′ and the second-second capping layer 226b″, the first-fourth capping layer 226d′ and the second-fourth capping layer 226d″ having higher refractive indexes are alternately laminated above the cathode electrode 123. By doing this, the reflectance is further increased to compensate for the front luminous efficiency while maintaining the visibility.

An encapsulation layer 150 may be disposed above the capping layers 226′ and 226″ configured as described above.

The encapsulation layer 150 may have a single layer structure or a multi-layered structure.

As described above, the encapsulation layer 150 may include a first encapsulation layer 150a, a second encapsulation layer 150b, and a third encapsulation layer 150c.

FIG. 9 is a table for comparing a luminous efficiency.

FIGS. 10A to 10D are graphs illustrating changes in visibility.

In FIG. 9, luminous efficiency of Comparative Embodiment and Experimental Embodiments 1, 2, and 3 in red, green, and blue are compared.

FIG. 10A illustrates a change in visibility of Comparative Embodiment, FIG. 10B illustrates a change in visibility of Experimental Embodiment 1, FIG. 10C illustrates a change in visibility of Experimental Embodiment 3, and FIG. 10D illustrates a change in visibility of Experimental Embodiment 4.

At this time, in Comparative Embodiment, a single capping layer having a high refractive index is used and in Experimental Embodiments 1, 2, and 3, a plurality of capping layers of a first capping layer having a low refractive index, a second capping having a high refractive index, and a third capping layer having a low refractive index is applied.

Here, the capping layer of Comparative Embodiment has a thickness of approximately 900 Å and the first capping layer, the second capping layer, and the third capping layer of Experimental Embodiments 1 and 2 have thicknesses of approximately 100 Å, 700 Å, and 100 Å, respectively.

Further, in Experimental Embodiments 2 and 3, the SM structure is applied to the anode and in Experimental Embodiment 3, capping layers having different thicknesses for each sub pixels from each other are applied. That is, the first capping layer, the second capping layer, and the third capping layer of the red sub pixel of Experimental Embodiments 3 have thicknesses of approximately 200 Å, 700 Å, and 200 Å, respectively. Further, the first capping layer, the second capping layer, and the third capping layer of the green sub pixel and the blue sub pixel have thicknesses of approximately 100 Å, 700 Å, and 100 Å, respectively.

Referring to FIG. 9, in Comparative Embodiment, it is understood that the luminous efficiencies in the red sub pixel, the green sub pixel, and the blue sub pixel are 60.7 cd/A, 156.3 cd/A, and 9.4 cd/A, respectively.

In Experimental Embodiment 1, it is understood that the luminous efficiencies in the red sub pixel, the green sub pixel, and the blue sub pixel are 61.3 cd/A, 156.2 cd/A, and 10.5 cd/A, respectively and are increased by 1.0%, −0.1%, and 13.7% as compared with Comparative Embodiment.

In Experimental Embodiment 2, it is understood that the luminous efficiencies in the red sub pixel, the green sub pixel, and the blue sub pixel are 62.9 cd/A, 157.5 cd/A, and 10.6 cd/A, respectively and are increased by 3.6%, 0.8%, and 14.7% as compared with Comparative Embodiment.

In Experimental Embodiment 3, it is understood that the luminous efficiencies in the red sub pixel, the green sub pixel, and the blue sub pixel are 68.1 cd/A, 157.5 cd/A, and 10.6 cd/A, respectively and are increased by 12.2%, 0.8%, and 14.7% as compared with Comparative Embodiment.

That is, it is understood that in all Experimental Embodiment 1 in which a plurality of capping layers having different refractive indexes is applied, Experimental Embodiment 2 in which the SM structure is additionally applied to Experimental Embodiment 1, and Experimental Embodiment 3 in which capping layers with different thicknesses from each other are applied to each sub pixels in Experimental Embodiment 2, the luminous efficiency is increased. Specifically, it is understood that in Experimental Embodiments 2 and 3, the luminous efficiency is significantly increased and in Experimental Embodiment 3, the luminous efficiency in the red sub pixel is very significantly increased.

In FIGS. 10A to 10D, an X-axis indicates an x-axis of a color coordinate and a Y-axis indicates a y-axis of the color coordinate.

The color coordinate is a scientific quantity which displays to distinguish colors after measuring the colors and coordinate values of red (700 nm), green (546.1 nm), and blue (435.8 nm) are represented on a coordinate system designated by the CIE in 1931.

In FIGS. 10A to 10D, a center first point indicates a color coordinate at a viewing angle of 0 degree, a second point indicates a color coordinate at a viewing angle of 15 degrees, and a third point indicates a color coordinate at a viewing angle of 30 degrees. Further, a fourth point indicates a color coordinate at a viewing angle of 45 degrees, and a fifth point indicates a color coordinate at a viewing angle of 60 degrees.

The smaller the change in the color coordinate from the first point to the fifth point, the smaller the change in the visibility according to the viewing angle.

Referring to FIGS. 10A to 10D, it is understood that in Experimental Embodiment 3 in which capping layers with different thicknesses are applied to individual sub pixels, a change in visibility according to the viewing angle is significantly reduced as compared with Comparative Embodiment and Experimental Embodiments 1 and 2.

For reference, in Comparative Embodiment, it is understood that color differences Au′v′ at 15 degrees, 30 degrees, 45 degrees and 60 degrees, with reference to 0 degree, are 0.004, 0.009, 0.003, and 0.013, respectively.

In Experimental Embodiment 1, it is understood that color differences Au′v′ at 15 degrees, 30 degrees, 45 degrees and 60 degrees, with reference to 0 degree, are 0.006, 0.011, 0.002, and 0.013, respectively.

In Experimental Embodiment 2, it is understood that color differences Au′v′ at 15 degrees, 30 degrees, 45 degrees and 60 degrees, with reference to 0 degree, are 0.004, 0.007, 0.005, and 0.010, respectively.

In contrast, in Experimental Embodiment 3, it is understood that color differences Au′v′ at 15 degrees, 30 degrees, 45 degrees and 60 degrees, with reference to 0 degree, are 0.004, 0.008, 0.002, and 0.001, respectively, which are reduced as compared with Comparative Embodiment and Experimental Embodiments 1 and 2.

Further, it is understood that in Comparative Embodiment, the reduction in luminance at 15 degrees, 30 degrees, 45 degrees, and 60 degrees with reference to 0 degree are 94.8%, 70.0%, 37.5%, and 18.4%, respectively.

It is understood that in Experimental Embodiment 1, the reduction in luminance at 15 degrees, 30 degrees, 45 degrees, and 60 degrees with reference to 0 degree are 94.2%, 69.4%, 36.7%, and 20.6%, respectively.

It is understood that in Experimental Embodiment 2, the reduction in luminance at 15 degrees, 30 degrees, 45 degrees, and 60 degrees with reference to 0 degree are 94.1%, 72.4%, 35.1%, and 17.4%, respectively.

It is understood that in Experimental Embodiment 3, the reduction in luminance at 15 degrees, 30 degrees, 45 degrees, and 60 degrees with reference to 0 degree are 96.1%, 72.3%, 36.6%, and 18.0%, respectively.

As described above, in Experimental Embodiment 1 in which a plurality of capping having different layers refractive indexes as compared with Comparative Embodiment, it is understood that the luminous efficiency is increased, but the change in visibility and the reduction in luminance are more significant.

Further, in the case of Experimental Embodiment 2 in which the SM structure is further applied to Experimental Embodiment 1, it is understood that the luminous efficiency is further increased by means of the increase in the reflectance.

In the case of Experimental Embodiment 3 in which capping layers having different thicknesses are applied to individual sub pixels in Experimental Embodiment 2, it is understood that the luminous efficiency is further increased in the red sub pixel as compared with Comparative Embodiment and the change in visibility is also improved much more. In this case, a total thickness of the plurality of capping layers in the red sub pixel is larger than that of the green sub pixel and the blue sub pixel and a thickness of the capping layer having a low refractive index in the red sub pixel may be larger than a thickness of the capping layer having a low refractive index of the green sub pixel and the blue sub pixel. Further, a thickness of the capping layer having a high refractive index may be larger than a thickness of the capping layer having a low refractive index.

Hereinafter, a manufacturing process of the display panel will be described in detail with reference to the drawing.

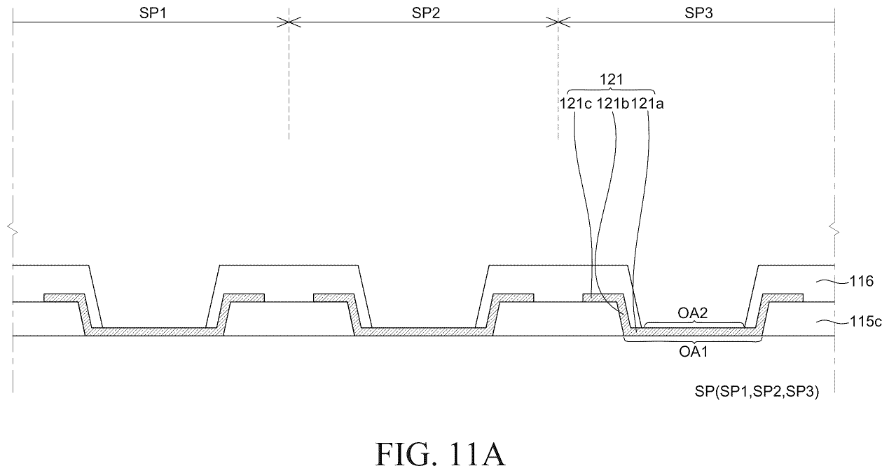

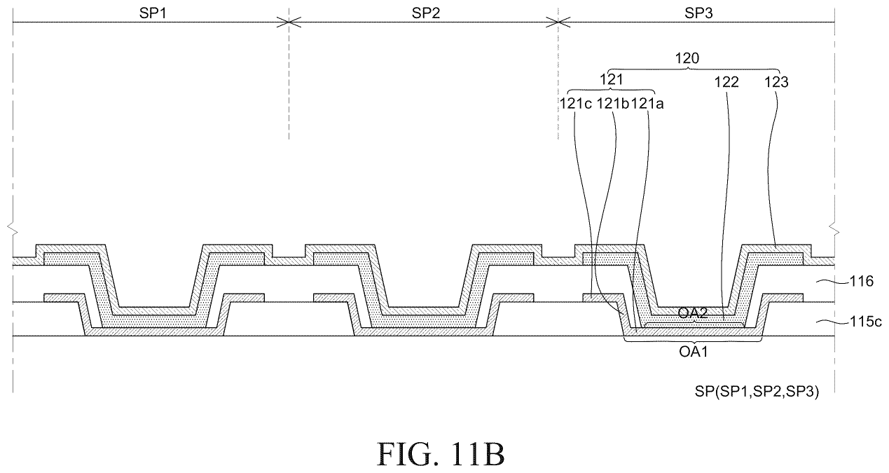

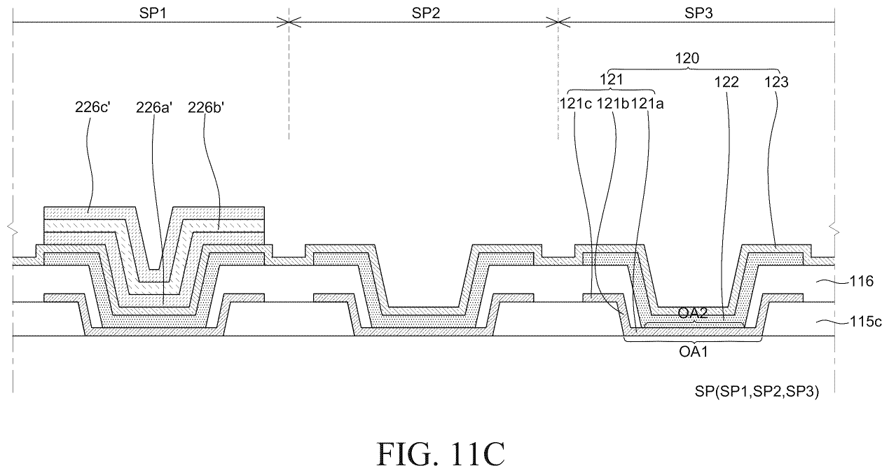

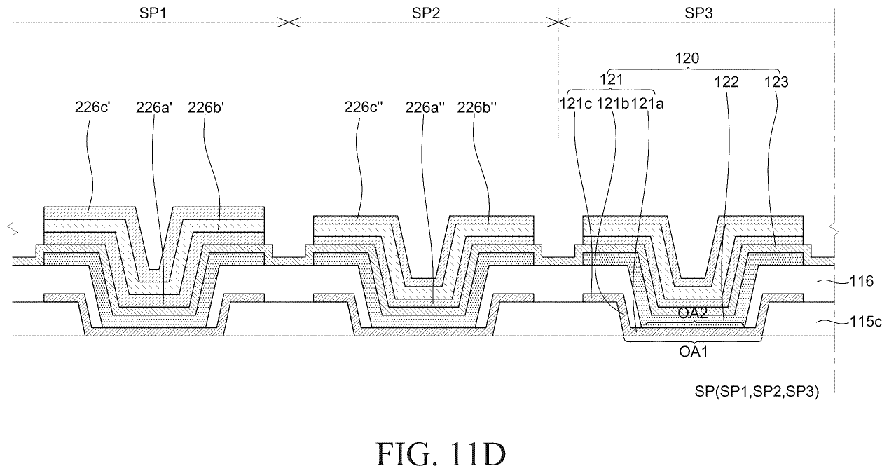

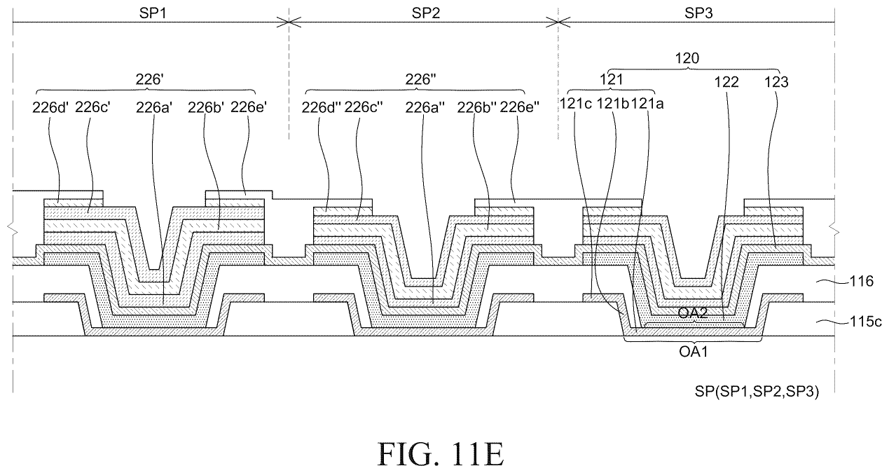

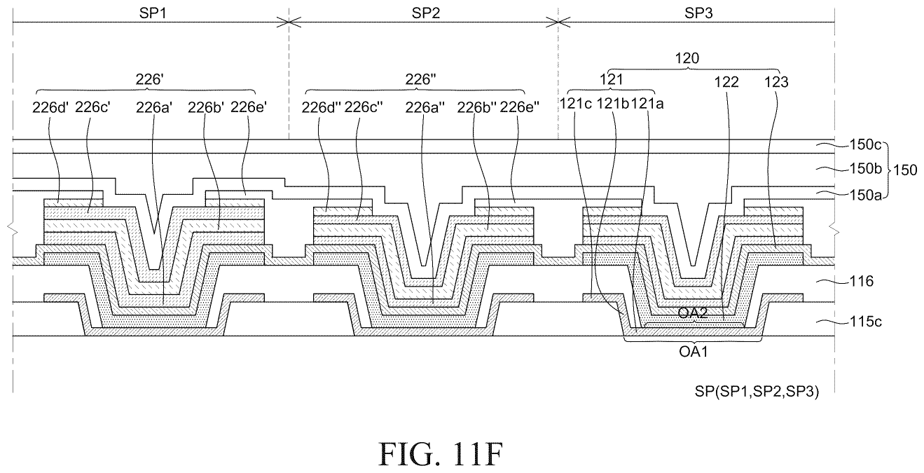

FIGS. 11A to 11F are views sequentially illustrating a manufacturing process of a display panel illustrated in FIG. 8.

For the convenience of description, a manufacturing process of configurations below the third planarization layer 115c is omitted.

Referring to FIG. 11A, a plurality of first sub pixels SP1, second sub pixels SP2, and third sub pixels SP3 may be disposed in the pixel area.

For example, the first sub pixel SP1 may be a red sub pixel.

For example, the second sub pixel SP2 may be a green sub pixel.

For example, the third sub pixel SP3 may be a blue sub pixel.

The third planarization layer 115c including the first open area OA1 may be formed in the first sub pixel SP1, the second sub pixel SP2, and the third sub pixel SP3.

The third planarization layer 115c may include a top surface and a side portion.

The anode electrode 121 may be formed on the third planarization layer 115c.

For example, the anode electrode 121 may be formed on the top surface and the side portion of the third planarization layer 115c and the top surface of the second planarization layer 115b. For example, the anode electrode 121 may be formed on the first open area OA1 and the top surface and the side portion of the third planarization layer 115c.

For example, the anode electrode 121 may include a first area 121a which has a surface substantially parallel to a surface of the second substrate 110b in the first open area OA1 and a second area 121b which extends from the first area 121a so that a surface has a predetermined angle with respect to the second substrate 110b. Further, for example, the first area 121a of the anode electrode 121 may correspond to the first open area OA1. For example, the second area 121b of the anode electrode 121 may correspond to a side portion of the third planarization layer 115c.

In the present disclosure, the second area 121b of the anode electrode 121 may configure the SM structure. The SM structure of the anode electrode 121 may be configured in the first open area OA1.

For example, the anode electrode 121 may include a third area 121c which extends from the second area 121b so that a surface is substantially parallel to a surface of the second substrate 110b. The third area 121c may correspond to the top surface of the third planarization layer 115c.

Thereafter, the bank 116 may be formed on the anode electrode 121 and the third planarization layer 115c. The bank 116 may cover the second area 121b and the third area 121c of the anode electrode 121. Further, the bank 116 may cover a part of the first area 121a of the anode electrode 121. For example, the bank 116 may cover a part of the edge of the first area 121a of the anode electrode 121.

For example, the bank 116 may include a second open area OA2 obtained by removing (opening) a part corresponding to the main emission area of each of the sub pixels SP1, SP2, and SP3.

For example, a part of the anode electrode 121 may be exposed by the second open area OA2.

Referring to FIG. 11B, the organic layer 122 may be disposed in the second open area OA2 of the bank 116 or in the vicinity thereof.

For example, the organic layer 122 may be formed on the anode electrode 121 exposed through the second open area OA2 of the bank 116. For example, the organic layer 122 may be formed in the second open area OA2 of the bank 116.

For example, the organic layer 122 may also be formed on a part of the top surface and the side portion of the bank 116 so as to cover the third area 121c of the end of the anode electrode 121 in the second open area OA2.

Thereafter, the cathode electrode 123 may be formed on the organic layer 122. For example, the cathode electrode 123 may be commonly formed in adjacent sub pixels SP1, SP2, and SP3.

Each of the sub pixels SP1, SP2, and SP3 may have different optical distances from each other. A first optical distance of the first sub pixel SP1 is larger than a second optical distance of the second sub pixel SP2 and a third optical distance of the third sub pixel SP3 and the second optical distance of the second sub pixel SP2 may be larger than the third optical distance of the third sub pixel SP3.

Thereafter, referring to FIG. 11C, the first-first capping layer 226a′ having a first refractive index, the first-second capping layer 226b′ having a second refractive index, and the first-third capping layer 226c′ having a third refractive index may be sequentially formed on the cathode electrode 123 of the first sub pixel SP1.

For example, the first-first capping layer 226a′, the first-second capping layer 226b′, and the first-third capping layer 226c′ may also be formed on a part of the top surface and a side portion of the cathode electrode 123. For example, the first-first capping layer 226a′, the first-second capping layer 226b′, and the first-third capping layer 226c′ may be formed on a part of the top surface and a side portion of the cathode electrode 123 so as to cover to the end of the organic layer 122 in the second open area OA2.

For example, the first-second capping layer 226b′ may be thicker than the first-first capping layer 226a′ and the first-third capping layer 226c′. For example, the first-second capping layer 226b′ may have a thickness of approximately 700 Å and the first-first capping layer 226a′ and the first-third capping layer 226c′ may have a thickness of approximately 200 Å, but the present disclosure is not limited thereto.

Thereafter, referring to FIG. 11D, the second-first capping layer 226a″ having a first refractive index, the second-second capping layer 226b″ having a second refractive index, and the second-third capping layer 226c″ having a third refractive index may be sequentially formed on the cathode electrodes 123 of the second sub pixel SP2 and the third sub pixel SP3.

For example, the second-first capping layer 226a″, the second-second capping layer 226b″, and the second-third capping layer 226c″ may also be formed on a part of the top surface and a side portion of the cathode electrode 123. For example, the second-first capping layer 226a″, the second-second capping layer 226b″, and the second-third capping layer 226c″ may be formed on a part of the top surface and a side portion of the cathode electrode 123 so as to cover to the end of the organic layer 122 in the second open area OA2.

For example, the second-second capping layer 226b″ may be thicker than the second-first capping layer 226a″ and the second-third capping layer 226c″. For example, the second-second capping may thickness of layer 226b″ have a approximately 700 Å and the second-first capping layer 226a″ and the second-third capping layer 226c″ may have a thickness of approximately 100 Å, but the present disclosure is not limited thereto.

Next, referring to FIG. 11E, the first-fourth capping layer 226d′ having a fourth refractive index and the second-fourth capping layer 226d″ having a fourth refractive index may be formed on the first-third capping layer 226c′ of the first sub pixel SP1 and the second-third capping layer 226c″ of the second sub pixel SP2 and the third sub pixel SP3, respectively.

The first-fourth capping layer 226d′ and the second-fourth capping layer 226d″ may be formed on the first-third capping layer 226c′ and the second-third capping layer 226c″ excluding the second open area OA2, respectively.

For example, the first-fourth capping layer 226d′ and the second-fourth capping layer 226d″ may be formed only above the third area 121c of the anode electrode 121 excluding the second open area OA2.

Next, the first-fifth capping layer 226e′ and the second-fifth capping layer 226e″ having a fifth refractive index may be formed above each of the first-fourth capping layer 226d′ and the second-fourth capping layer 226d″ excluding the second open area OA2. The first-fifth capping layer 226e′ and the second-fifth capping layer 226e″ may extend to the adjacent sub pixel to cover the first-fourth capping layer 226d′ and the second-fourth capping layer 226d″ excluding the second open area OA2.

Here, the first refractive index, the third refractive index, and the fifth refractive index may be lower than the second refractive index and the fourth refractive index. For example, the first refractive index, the third refractive index, and the fifth refractive index may be 1.5 or lower and the second refractive index and the fourth refractive index may be 1.8 or higher.

Next, referring to FIG. 11F, an encapsulation layer 150 may be formed above the capping layers 226′ and 226″ configured as described above.

The encapsulation layer 150 may have a single layer structure or a multi-layered structure.

As described above, the encapsulation layer 150 may include a first encapsulation layer 150a, a second encapsulation layer 150b, and a third encapsulation layer 150c.

The first-fifth capping layer 226e′ and the second-fifth capping layer 226e″ of the present disclosure may also partially extend to the second open area OA2 to cover side surfaces of the first-fourth capping layer 226d′ and the second-fourth capping layer 226d″, which will be described with reference to the drawing.

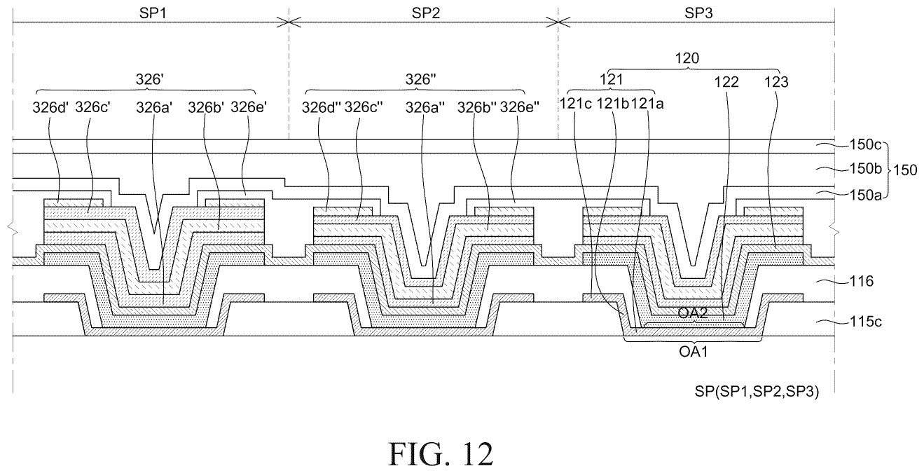

FIG. 12 is a cross-sectional view illustrating a pixel structure of a third exemplary embodiment of the present disclosure.

In a third exemplary embodiment of the present disclosure of FIG. 12, only capping layers 326′ and 326″ have different configurations from that of the second exemplary embodiment of the present disclosure of FIG. 8 described above, but other configurations are substantially the same so that a redundant description will be omitted.

Referring to FIG. 12, a light emitting diode 120 formed of an anode electrode 121, an organic layer 122, and a cathode electrode 123 may be disposed on the third planarization layer 115c.

Capping layers 326′ and 326″ may be disposed on the cathode electrode 123.

The capping layers 326′ and 326″ of the third exemplary embodiment of the present disclosure may include a first capping layer 326′ and a second capping layer 326″.

For example, the first capping layer 326′ may be disposed in the first sub pixel SP1 and the second capping layer 326″ may be disposed in the second sub pixel SP2 and the third sub pixel SP3, but are not limited thereto.

The capping layers 326′ and 326″ of the third exemplary embodiment of the present disclosure may be configured by a plurality of layers.

For example, the first capping layer 326′ of the third exemplary embodiment of the present disclosure may be configured with a multi-layered structure of a first-first capping layer 326a′ having a first refractive index, a first-second capping layer 326b′ having a second refractive index, and a first-third capping 326c′ having layer a third refractive index.

For example, the second capping layer 326″ of the third exemplary embodiment of the present disclosure may be configured with a multi-layered structure of a second-first capping layer 326a″ having a first refractive index, a second-second capping layer 326b″ having a second refractive index, and a second-third capping layer 326c″ having a third refractive index.

Further, the first capping layer 326′ according to the third exemplary embodiment of the present disclosure may further include a first-fourth capping layer 326d′ having a fourth refractive index disposed on the first-third capping layer 326c′ excluding the second open area OA2 and a first-fifth capping layer 326e′ disposed on the first-fourth capping layer 326d′ excluding the second open area OA2. For example, the first-fourth capping layer 326d′ may be disposed only above the third area 121c of the anode electrode 121 excluding the second open area OA2 and the first-fifth capping layer 326e′ may partially extend to the second open area OA2 so as to cover a side surface of the first-fourth capping layer 326d′ excluding the second open area OA2. A part of the first-fifth capping layer 326e′ may be in contact with the top surface of the first-third capping layer 326c′.

Further, the second capping layer 326″ according to the third exemplary embodiment of the present disclosure may further include a second-fourth capping layer 326d″ having a fourth refractive index disposed on the second-third capping layer 326c″ excluding the second open area OA2 and a second-fifth capping layer 326e″ having a fifth refractive index disposed on the second-fourth capping layer 326d″ excluding the second open area OA2. Further, for example, the second-fourth capping layer 326d″ may be disposed only above the third area 121c of the anode electrode 121 excluding the second open area OA2 and the second-fifth capping layer 326e′ may partially extend to the second open area OA2 so as to cover a side surface of the second-fourth capping layer 326d″ excluding the second open area OA2. A part of the second-fifth capping layer 326e″ may be in contact with the top surface of the second-third capping layer 326c″.

An encapsulation layer 150 may be disposed above the capping layers 326′ and 326″ configured as described above.

The exemplary embodiments of the present disclosure can also be described as follows:

According to an aspect of the present disclosure, there is provided a display device. The display device comprises a substrate including a plurality of sub pixels, a transistor disposed above the substrate, a planarization layer which is disposed above the transistor and has a first open area, an anode electrode which is disposed in the first open area and a side portion and a part of a top surface of the planarization layer opposite to the first open area, a bank which covers a part of the anode electrode and has a second open area corresponding to the first open area, an organic layer which is disposed on the anode electrode exposed by the second open area, a cathode electrode disposed on the organic layer and a capping layer which is disposed above the cathode electrode and includes a first capping layer having a first refractive index, a second capping layer having a second refractive index, and a third capping layer having a third refractive index, the first refractive index and the third refractive index may be relatively lower than the second refractive index.

The first open area may have a width larger than that of the second open area.

The anode electrode, the organic layer, and the cathode electrode may configure a light emitting diode, the light emitting diode may form a main emission area, a side portion of the anode electrode may form a reflective emission area, the reflective emission area may be formed in the vicinity of the main emission area, and a non-emission area may be formed between the main emission area and the reflective emission area.

The anode electrode may include a reflective layer, the cathode electrode may be configured by a transflective electrode, and the cathode electrode may be commonly disposed in adjacent sub pixels.

The organic layer may be disposed in the second open area and a side portion and a part of a top surface of the bank may opposite to the second open area.

The first capping layer, the second capping layer, and the third capping layer may be disposed to an end of the organic layer in the second open area.

The second capping layer may have a thickness larger than those of the first capping layer and the third capping layer.

The capping layer may further include a fourth capping layer which is disposed on the third capping layer excluding the second open area and has a fourth refractive index and a fifth capping layer which is disposed on the fourth capping layer excluding the second open area and has a fifth refractive index, and the fifth refractive index may be relatively lower than the fourth refractive index.

The fifth capping layer may extend to the adjacent sub pixel to cover the fourth capping layer excluding the second open area.

The fifth capping layer may partially extend to the second open area to cover the side surface of the fourth capping layer.

The plurality of sub pixels may include a plurality of first sub pixels, second sub pixels, and third sub pixels and the first sub pixel may be a red sub pixel, the second sub pixel may be a green sub pixel, and the third sub pixel may be a blue sub pixel.

A first optical distance which is a distance between the anode electrode and the cathode electrode of the first sub pixel may be larger than a second optical distance of the second sub pixel and a third optical distance of the third sub pixel and the second optical distance may be larger than the third optical distance.

The capping layer may further include a first capping layer disposed in the first sub pixel and a second capping layer which is disposed in the second sub pixel and the third sub pixel.

The first capping layer may include a first-first capping layer having the first refractive index, a first-second capping layer having the second refractive index, and a first-third capping layer having the third refractive index and the second capping layer may include a second-first capping layer having the first refractive index, a second-second capping layer having the second refractive index, and a second-third capping layer having the third refractive index.

The first-first capping layer, the first-second capping layer, and the first-third capping layer may be disposed to the end of the organic layer in the second open area and the second-first capping layer, the second-second capping layer, and the second-third capping layer may be disposed to the end of the organic layer in the second open area.

The first-second capping layer may be thicker than the first-first capping layer and the first-third capping layer and the second-second capping layer may be thicker than the second-first capping layer and the second-third capping layer.

The first-first capping layer and the first-third capping layer may be thicker than the second-first capping layer and the second-third capping layer.

The first capping layer may further include a first-fourth capping layer which is disposed on the first-third capping layer excluding the second open area and has a fourth refractive index and a first-fifth capping layer which is disposed on the first-fourth capping layer excluding the second open area and has a fifth refractive index and the second capping layer may further include a second-fourth capping layer which is disposed on the second-third capping layer excluding the second open area and has the fourth refractive index and a second-fifth capping layer which is disposed on the second-fourth capping layer excluding the second open area and has the fifth refractive index, the fifth refractive index may be relatively lower than the fourth refractive index.

The first-fifth capping layer may extend to the adjacent sub pixel to cover the first-fourth capping layer excluding the second open area and the second-fifth capping layer may extend to the adjacent sub pixel to cover the second-fourth capping layer excluding the second open area. The first-fifth capping layer may partially extend to the second open area to cover a side surface of the first-fourth capping layer and the second-fifth capping layer partially may extend to the second open area to cover a side surface of the second-fourth capping layer.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including a plurality of sub pixels;
a transistor disposed above the substrate;
a planarization layer which is disposed above the transistor and has a first open area;
an anode electrode which is disposed in the first open area and a side portion and a part of a top surface of the planarization layer opposite to the first open area;
a bank which covers a part of the anode electrode and has a second open area corresponding to the first open area;
an organic layer which is disposed on the anode electrode exposed by the second open area;
a cathode electrode disposed on the organic layer; and
a capping layer which is disposed above the cathode electrode and includes a first capping layer having a first refractive index, a second capping layer having a second refractive index, and a third capping layer having a third refractive index,
wherein the first refractive index and the third refractive index are relatively lower than the second refractive index.

2. The display device according to claim 1, wherein the first open area has a width larger than that of the second open area.

3. The display device according to claim 1, wherein the anode electrode, the organic layer, and the cathode electrode configure a light emitting diode, and
wherein the light emitting diode forms a main emission area, a side portion of the anode electrode forms a reflective emission area, the reflective emission area is formed in the vicinity of the main emission area, and a non-emission area is formed between the main emission area and the reflective emission area.

4. The display device according to claim 1, wherein the anode electrode includes a reflective layer, the cathode electrode is configured by a transflective electrode, and the cathode electrode is commonly disposed in adjacent sub pixels.

5. The display device according to claim 1, wherein the organic layer is disposed in the second open area and a side portion and a part of a top surface of the bank opposite to the second open area.

6. The display device according to claim 5, wherein the first capping layer, the second capping layer, and the third capping layer are disposed to an end of the organic layer in the second open area.

7. The display device according to claim 1, wherein the second capping layer has a thickness larger than those of the first capping layer and the third capping layer.

8. The display device according to claim 1, wherein the capping layer further includes:
a fourth capping layer which is disposed on the third capping layer excluding the second open area and has a fourth refractive index; and
a fifth capping layer which is disposed on the fourth capping layer excluding the second open area and has a fifth refractive index, and
wherein the fifth refractive index is relatively lower than the fourth refractive index.

9. The display device according to claim 8, wherein the fifth capping layer extends to the adjacent sub pixel to cover the fourth capping layer excluding the second open area.

10. The display device according to claim 8, wherein the fifth capping layer partially extends to the second open area to cover the side surface of the fourth capping layer.

11. The display device according to claim 1, wherein the plurality of sub pixels includes a plurality of first sub pixels, second sub pixels, and third sub pixels and the first sub pixel is a red sub pixel, the second sub pixel is a green sub pixel, and the third sub pixel is a blue sub pixel.

12. The display device according to claim 11, wherein a first optical distance which is a distance between the anode electrode and the cathode electrode of the first sub pixel is larger than a second optical distance of the second sub pixel and
wherein a third optical distance of the third sub pixel and the second optical distance is larger than the third optical distance.

13. The display device according to claim 11, wherein the capping layer further includes:
a first capping layer disposed in the first sub pixel; and
a second capping layer which is disposed in the second sub pixel and the third sub pixel.

14. The display device according to claim 13, wherein the first capping layer includes a first-first capping layer having the first refractive index, a first-second capping layer having the second refractive index, and a first-third capping layer having the third refractive index and
wherein the second capping layer includes a second-first capping layer having the first refractive index, a second-second capping layer having the second refractive index, and a second-third capping layer having the third refractive index.

15. The display device according to claim 14, wherein the first-first capping layer, the first-second capping layer, and the first-third capping layer are disposed to the end of the organic layer in the second open area and
wherein the second-first capping layer, the second-second capping layer, and the second-third capping layer are disposed to the end of the organic layer in the second open area.

16. The display device according to claim 14, wherein the first-second capping layer is thicker than the first-first capping layer and the first-third capping layer and the second-second capping layer is thicker than the second-first capping layer and the second-third capping layer.

17. The display device according to claim 16, wherein the first-first capping layer and the first-third capping layer are thicker than the second-first capping layer and the second-third capping layer.

18. The display device according to claim 14, wherein the first capping layer further includes:
a first-fourth capping layer which is disposed on the first-third capping layer excluding the second open area and has a fourth refractive index; and
a first-fifth capping layer which is disposed on the first-fourth capping layer excluding the second open area and has a fifth refractive index; and
wherein the second capping layer further includes:
a second-fourth capping layer which is disposed on the second-third capping layer excluding the second open area and has the fourth refractive index; and
a second-fifth capping layer which is disposed on the second-fourth capping layer excluding the second open area and has the fifth refractive index,
the fifth refractive index is relatively lower than the fourth refractive index.

19. The display device according to claim 18, wherein the first-fifth capping layer extends to the adjacent sub pixel to cover the first-fourth capping layer excluding the second open area and
wherein the second-fifth capping layer extends to the adjacent sub pixel to cover the second-fourth capping layer excluding the second open area.

20. The display device according to claim 18, wherein the first-fifth capping layer partially extends to the second open area to cover a side surface of the first-fourth capping layer and
wherein the second-fifth capping layer partially extends to the second open area to cover a side surface of the second-fourth capping layer.
